(19) United States
(12) Patent Application Publication
(10) Pub. No.: US 2025/0386674 A1
(43) Pub. Date: Dec. 18, 2025

(54) DISPLAY DEVICE, METHOD OF MANUFACTURING DISPLAY DEVICE, AND ELECTRONIC DEVICE INCLUDING DISPLAY DEVICE

(71) Applicant: Samsung Display Co., LTD., Yongin-si (KR)

(72) Inventor: Yoon A KIM, Yongin-si (KR)

(21) Appl. No.: 19/097,116

(22) Filed: Apr. 1, 2025

(30) Foreign Application Priority Data
Jun. 18, 2024 (KR) 10-2024-0079035
Sep. 12, 2024 (KR) 10-2024-0124983

(51) Int. Cl. H10K 59/122; H10K 59/12

(52) U.S. Cl. CPC H10K 59/122; H10K 59/1201

(57) ABSTRACT

A display device includes: a light emitting element disposed on a substrate, the light emitting element including an anode electrode, an emission structure, and a cathode electrode, which are electrically connected to each other; and a pixel defining layer adjacent to the anode electrode. A trench is defined in the pixel defining layer and penetrate at least a portion of the pixel defining layer, and an upper separator is defined in an upper surface of the pixel defining layer and has a structure different from a structure of the trench.

This application claims priority to Korean Patent Application No. 10-2024-0079035, filed on Jun. 18, 2024, and Korean Patent Application No. 10-2024-0124983, filed on Sep. 12, 2024, and all the benefits accruing therefrom under 35 U.S.C. § 119, the content of which in its entirety is herein incorporated by reference

### BACKGROUND

### 1. Field

The disclosure generally relates to a display device, a method of manufacturing a display device, an electronic device including a display device.

### 2. Related Art

Recently, as interest in information displays is increased, research and development of display devices are being continuously conducted.

The display device may include sub-pixels, each comprising an organic light-emitting diode (“OLED”). As an active light-emitting display element, the OLED has advantages such as a wide viewing angle, excellent contrast, low-voltage drive capability, lightweight and thin form factor, and fast response speed.

### SUMMARY

Electrical signals respectively supplied to sub-pixels adjacent to each other need to be distinguished from each other. For example, there may occur a risk that crosstalk will occur between electrical signals due to lateral leakage occurring between sub-pixels. Accordingly, a display device, in which a risk such as lateral leakage may be reduced, is desired.

Embodiments provide a display device, a method of manufacturing a display device, an electronic device including a display device, in which a risk such as lateral leakage may be reduced, and accordingly, display quality may be improved.

In an embodiment of the disclosure, there is provided a display device including: a light-emitting element disposed on a substrate, the light-emitting element including an anode electrode, an emission structure, and a cathode electrode, which are electrically connected to each other; and a pixel defining layer next (adjacent) to the anode electrode. The pixel defining layer defines a trench which penetrates at least a portion of the pixel defining layer and an upper separator which is defined in an upper surface of the pixel defining layer and has a structure different from a structure of the trench.

In an embodiment, the pixel defining layer may include a lower separator which is defined in an edge of an upper surface of the anode electrode and has an undercut structure.

In an embodiment, the upper surface of the anode electrode may not contact the pixel defining layer, and a side surface of the anode electrode may be directly next (adjacent) to the pixel defining layer.

In an embodiment, the trench may entirely penetrate the pixel defining layer, and the upper separator may partially penetrate the pixel defining layer.

In an embodiment, the upper separator may have a trench structure, and have a depth lower than a depth of the trench.

In an embodiment, the upper separator may have a polygonal or curved cross-sectional profile.

In an embodiment, the upper separator may include a first upper separator disposed at a side of the trench and a second upper separator disposed at an opposite side of the trench opposite to the side of the trench.

In an embodiment, the upper separator may have a protruding structure at the upper surface of the pixel defining layer.

In an embodiment, the upper separator may have a polygonal or curved cross-sectional profile.

In an embodiment, the trench may include a first trench and a second trench, which are spaced apart from each other. The upper separator may include a first upper separator disposed at a side of the first trench, a second upper separator disposed between an opposite side of the first trench opposite to the side of the first trench and a side of the second trench, and a third upper separator disposed at an opposite side of the second trench opposite to the side of the second trench.

In an embodiment, the pixel defining layer may include a lower separator which is defined in an edge of an upper surface of the anode electrode and has an undercut structure. The upper separator may be defined between the lower separator and the trench.

In an embodiment, the pixel defining layer may further define: a lower separator which is defined in an edge of an upper surface of the anode electrode and has an undercut structure; and an intermediate separator defined on the lower separator. The intermediate separator may be a cavity in which a portion of a side surface of the pixel defining layer is recessed.

In an embodiment, the pixel defining layer may define a lower separator which is defined in an edge of an upper surface of the anode electrode and has an undercut structure. The pixel defining layer may include a first pixel defining layer and a second pixel defining layer on the first pixel defining layer, which include different materials from each other. The first pixel defining layer may have a width narrower than a width of the second pixel defining layer. The first pixel defining layer may not cover the upper surface of the anode electrode, may be directly next (adjacent) to a side surface of the anode electrode, and may be directly next (adjacent) to the lower separator.

In an embodiment, the second pixel defining layer may include a (2-1)th pixel defining layer and a (2-2)th pixel defining layer, which are spaced apart from each other. The pixel defining layer may include an intermediate pixel defining layer which has a width wider than a width of the second pixel defining layer and is disposed between the (2-1)th pixel defining layer and the (2-2)th pixel defining layer.

In an embodiment, the display device may be an organic light-emitting diode (“OLED”)-on-silicon (“OLEDOS”) display device.

In an embodiment of the disclosure, there is provided a display device including: a light-emitting element disposed on a substrate, the light-emitting element including an anode electrode, an emission structure, and a cathode electrode, which are electrically connected to each other; and a pixel defining layer next (adjacent) to the anode electrode. The pixel defining layer includes a first pixel defining structure and a second pixel defining structure on the first pixel defining structure, and each of the first pixel defining structure and a second pixel defining structure defines a lower separator having an undercut structure and an upper separator partially penetrating each of the first pixel defining structure and the second pixel defining structure.

In an embodiment of the disclosure, there is provided a method of manufacturing a display device. The method includes: patterning an anode electrode on a substrate; patterning a base pixel defining layer having an undercut structure on the anode electrode; forming a pixel defining layer defining a trench by removing at least a portion of the base pixel defining layer; forming an emission structure to cover the anode electrode and the pixel defining layer; and forming a cathode electrode on the emission structure.

In an embodiment, the forming the pixel defining layer may include forming an upper separator having a trench structure by removing at least a portion of the base pixel defining layer. The upper separator and the trench may be defined in a same process. The patterning the base pixel defining layer may include: patterning a first photoresist layer on the anode electrode; forming the base pixel defining layer covering an upper surface of the first photoresist layer and a side surface of the anode electrode; and removing the first photoresist layer.

In an embodiment, the forming the pixel defining layer may include: patterning, on the base pixel defining layer, a second photoresist layer including a (2-1)th photoresist layer and a (2-2)th photoresist layer, which have different heights, using a photomask including a half-tone portion; and defining the trench and the upper separator by performing an etching process on the base pixel defining layer, based on the second photoresist layer.

In an embodiment, the forming the pixel defining layer may include: patterning an upper layer on the base pixel defining layer; and defining an upper separator having a protruding structure by etching the upper layer.

In an embodiment of the disclosure, there is provided an electronic device including: a processor configured to provide input image data; a display device configured to display an image based on the input image data, the display device including sub-pixel areas; and a power supply configured to supply power to the display device. The display device may include: a light-emitting element disposed on a substrate, the light-emitting element including an anode electrode, an emission structure, and a cathode electrode, which are electrically connected to each other; and a pixel defining layer next (adjacent) to the anode electrode. The pixel defining layer defines a trench which penetrates at least a portion of the pixel defining layer and an upper separator which is defined in an upper surface of the pixel defining layer and may have a structure different from a structure of the trench

### BRIEF DESCRIPTION OF THE DRAWINGS

Embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the embodiments to those skilled in the art.

In the drawing figures, dimensions may be exaggerated for clarity of illustration. It will be understood that when an element is also referred to as being “between” two elements, it may be the only element between the two elements, or one or more intervening elements may also be present. Like reference numerals refer to like elements throughout.

FIG. 1 is a schematic plan view illustrating an embodiment of a display device in accordance with the disclosure.

FIG. 2 is a schematic exploded perspective view illustrating an embodiment of a display device in accordance with the disclosure.

FIG. 3 is a schematic plan view illustrating an embodiment of a pixel in accordance with the disclosure.

FIG. 4 is a schematic plan view illustrating another embodiment of a pixel in another embodiment of the disclosure.

FIG. 5 is a schematic plan view illustrating another embodiment of a pixel in another embodiment of the disclosure.

FIG. 6 is a schematic cross-sectional view illustrating an embodiment of a display device in accordance with the disclosure.

FIG. 7 is a schematic block diagram illustrating an embodiment of a relationship between a pixel defining layer and an emission structure in accordance with the disclosure.

FIG. 8 is a schematic cross-sectional view illustrating an embodiment of an emission structure in accordance with the disclosure.

FIG. 9 is a schematic cross-sectional view illustrating an embodiment of an emission structure in accordance with the disclosure.

FIGS. 10 to 17 are schematic cross-sectional views illustrating an embodiment of an anode electrode and a pixel defining layer in accordance with the disclosure.

FIGS. 18 to 23 are schematic cross-sectional views illustrating an embodiment of process steps of a method of manufacturing a display device in accordance with the disclosure.

FIGS. 24 to 28 are schematic cross-sectional views illustrating an embodiment of process steps of a method of manufacturing a display device in accordance with the disclosure.

FIG. 29 is a block diagram illustrating an embodiment of the electronic device.

FIG. 30 is a perspective view illustrating an application embodiment of the electronic device shown in FIG. 29.

FIG. 31 is a view illustrating a head mounted display device shown in FIG. 30, which is worn by a user.

### DETAILED DESCRIPTION

The disclosure may apply various changes and different shape, therefore only illustrate in detail with illustrative embodiments. However, the embodiments do not limit to particular shapes but apply to all the change and equivalent material and replacement. The drawings included are illustrated a fashion where the drawing figures are expanded for the better understanding.

It will be understood that, although the terms “first”, “second”, etc. may be used herein to describe various elements, these elements should not be limited by these terms. These terms are only used to distinguish one element from another element. Thus, a “first” element discussed below could also be termed a “second” element without departing from the teachings of the disclosure. As used herein, the singular forms are intended to include the plural forms as well, unless the context clearly indicates otherwise.

It will be further understood that the terms “includes” and/or “including”, when used in this specification, specify the presence of stated features, integers, steps, operations, elements, and/or components, but do not preclude the presence and/or addition of one or more other features, integers, steps, operations, elements, components, and/or groups thereof. Further, an expression that an element such as a layer, region, substrate or plate is placed “on” or “above” another element indicates not only a case where the element is placed “directly on” or “just above” the other element but also a case where a further element is interposed between the element and the other element. On the contrary, an expression that an element such as a layer, region, substrate or plate is placed “beneath” or “below” another element indicates not only a case where the element is placed “directly beneath” or “just below” the other element but also a case where a further element is interposed between the element and the other element.

The disclosure generally relates to a display device, a method of manufacturing a display device, an electronic device including a display device. Hereinafter, a display device, a method of manufacturing a display device, an electronic device including a display device in an embodiment of the disclosure will be described with reference to the accompanying drawings.

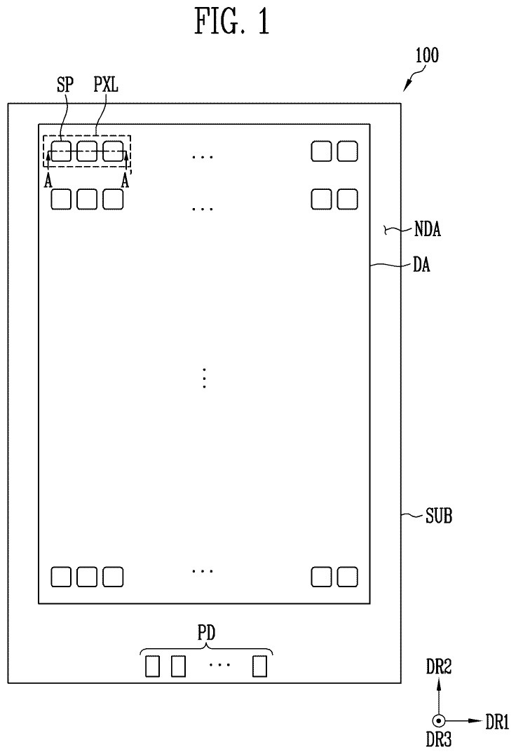

FIG. 1 is a schematic plan view illustrating an embodiment of a display device in accordance with the disclosure.

Referring to FIG. 1, a display device 100 in an embodiment of the disclosure may emit light.

The display device 100 may include a display area DA and a non-display area NDA. The display device may display an image through the display area DA. The non-display area NDA may be disposed at the periphery of the display area DA.

The display device 100 may include a substrate SUB, sub-pixels SP, and pads PD. In the disclosure, an area in which the sub-pixels SP are disposed may be referred to as a sub-pixel area.

When the display device 100 is used as a display screen of a head mounted display (“HMD”), a virtual reality (“VR”) device, a mixed reality (“MR”) device, an augmented reality (“AR”) device, or the like, the display device 100 may be disposed substantially close to eyes of a user. The sub-pixels SP having a relatively high degree of integration may be desired. In order to increase the degree of integration of the sub-pixels SP, the substrate SUB may be provided as a silicon substrate. The sub-pixels SP may be formed on the substrate SUB as the silicon substrate. The display device 100 including a plurality of layers formed on the substrate SUB as the silicon substrate may be also referred to as an organic light-emitting diode (“OLED”)-on-silicon (“OLEDOS”) display device.

The sub-pixels SP may be disposed in the display area DA on the substrate SUB. The sub-pixels SP may be arranged in a matrix form along a first direction DR1 and a second direction DR2 intersecting the first direction DR1. However, the disclosure is not limited thereto. In an embodiment, the sub-pixels SP may be arranged in a zigzag form along the first direction DR1 and the second direction DR2, for example. In an embodiment, the sub-pixels SP may be disposed in a PENTILE™ form, for example. The first direction DR1 may be a row direction, and the second direction DR2 may be a column direction.

A plane defined in this specification, is a plane extending in a first direction DR1 and a second direction DR2, and may be defined with respect to a plane on which the substrate SUB is disposed. In some embodiments, a third direction DR3 may be the thickness direction of the substrate SUB. The third direction DR3 may be a light emission direction of the display device 100.

The sub-pixels SP may have various shapes in a plan view, and the shape of the sub-pixels SP is not limited to a particular embodiment.

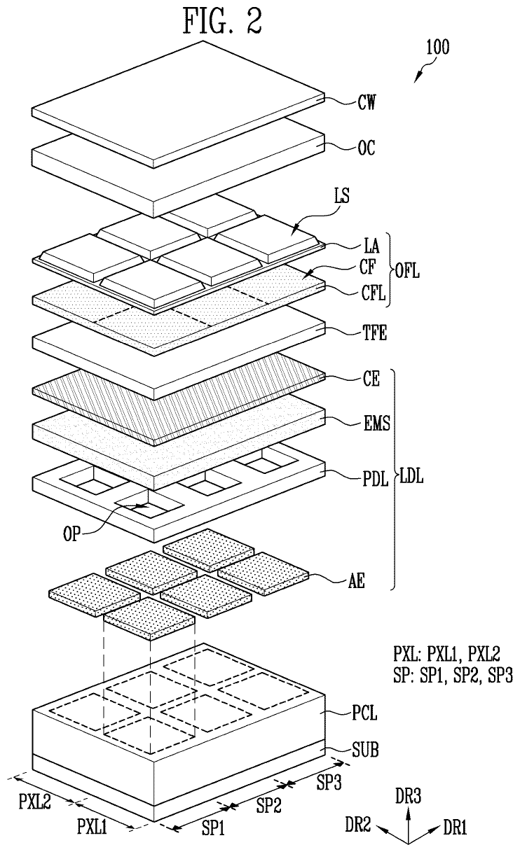

Each of the sub-pixels SP may include at least one light-emitting element LD (refer to FIG. 2) which generates light. Accordingly, each of the sub-pixels SP may generate light of a predetermined color such as red, green, blue, cyan, magenta or yellow. Two or more sub-pixels SP among the sub-pixels SP may constitute a pixel PXL. In an embodiment, three sub-pixels SP may constitute a pixel PXL as shown in FIG. 1, for example.

Hereinafter, an embodiment in which the sub-pixels SP includes a first sub-pixel SP1 providing light of a first color (e.g., red), a second sub-pixel SP2 providing light of a second color (e.g., green), and a third sub-pixel SP3 providing light of a third color (e.g., blue) will be mainly described.

In some embodiments, the first sub-pixel SP1 is a red pixel and may provide light in a wavelength band of 600 nanometers (nm) to 750 nm. The second sub-pixel SP2 is a green pixel and may provide light in a wavelength band of 480 nm to 560 nm. The third sub-pixel SP3 is a blue pixel and may provide light in a wavelength band of 370 nm to 460 nm.

A component for controlling the sub-pixels SP may be disposed in the non-display area NDA on the substrate SUB. In an embodiment, lines connected to the sub-pixels SP (e.g., gate lines, data lines, or the like, which are used to drive the sub-pixels SP) may be disposed in the non-display area NDA, for example. In addition, a gate driver, a data driver, a voltage generator, a controller, a temperature sensor, or the like, which are used to acquire driving signals supplied to the sub-pixels SP, may be integrated in the non-display area NDA of the display device 100. However, the disclosure is not limited thereto.

The pads PD may be disposed in the non-display area NDA on the substrate SUB. The pads PD may be electrically connected to the sub-pixels SP through the lines. In an embodiment, the pads PD may be connected to the sub-pixels SP through the data lines, for example.

The pads PD may interface components in the display area DA and the non-display area NDA with other components of the display device 100. In an embodiment, voltages and signals, which are desired for operations of components included in the display device 100, may be provided from a driver integrated circuit through the pads PD. In an embodiment, the data lines may be electrically connected to the driver integrated circuit through the pads PD, for example. In an embodiment, power voltages for driving the sub-pixels SP may be received from the driver integrated circuit through the pads PD, for example. In an embodiment, a gate control signal for controlling the gate driver may be transmitted to the gate driver from the driver integrated circuit through the pads PD, for example.

In an embodiment, a circuit board may be electrically connected to the pads PD, using a conductive adhesive member such as an anisotropic conductive film. The circuit board may be a flexible printed circuit board (“FPCB”) or a flexible film, which has a flexible material. The driver integrated circuit may be disposed (e.g., mounted) on the circuit board to be electrically connected to the pads PD.

In an embodiment, the display area DA may have various shapes. The display area DA may have a closed-loop shape including linear sides and/or curved sides. In an embodiment, the display area DA may have shapes such as a polygon, a circle, a semicircle, and an ellipse, for example.

In an embodiment, the display device 100 may have a flat display surface. In other embodiments, the display device 100 may at least partially have a round display surface. In an embodiment, the display device 100 may be bendable, foldable or rollable. The display device 100 and/or the substrate SUB may include materials having flexibility.

FIG. 2 is a schematic exploded perspective view illustrating an embodiment of a display device in accordance with the disclosure. In FIG. 2, for clear and brief description, a portion of the display device 100, which corresponds to two pixels PXL1 and PXL2 among pixels PXL, may be schematically illustrated. A portion of the display device 100, which corresponds to remaining (the other) pixels, may also be configured identically to the portion of the display device 100, which correspond to the two pixels PXL1 and PXL2.

Referring to FIG. 2, each of first and second pixels PXL1 and PXL2 may include first to third sub-pixels SP1 to SP3. However, the disclosure is not limited thereto. In an embodiment, each of the first and second pixels PXL1 and PXL2 may include four sub-pixels or include two sub-pixels, for example.

In FIG. 2, it may be illustrated that the first to third sub-pixels SP1 to SP3 may have quadrangular shapes when viewed in the third direction DR3 intersecting the first and second directions DR1 and DR2, and have the same size as each other. However, the disclosure is not limited thereto. The first to third sub-pixels SP1 to SP3 may be modified to have various shapes.

The display device 100 may include a substrate SUB, a pixel circuit layer PCL, a light-emitting element layer LDL, an encapsulation layer TFE, an optical functional layer OFL, an overcoat layer OC, and a cover window CW.

In an embodiment, the substrate SUB may include a silicon wafer substrate formed using a semiconductor process. The substrate SUB may include a semiconductor material suitable for forming circuit elements. In an embodiment, the semiconductor material may include silicon, germanium, and/or silicon-germanium, for example. The substrate SUB may be provided from a bulk wafer, an epitaxial layer, a silicon on insulator (“SOI”) layer, a semiconductor on insulator (“SeOI”) layer, or the like. In other embodiments, the substrate SUB may include a glass substrate. In still other embodiments, the substrate SUB may include a polyimide (“PI”) substrate.

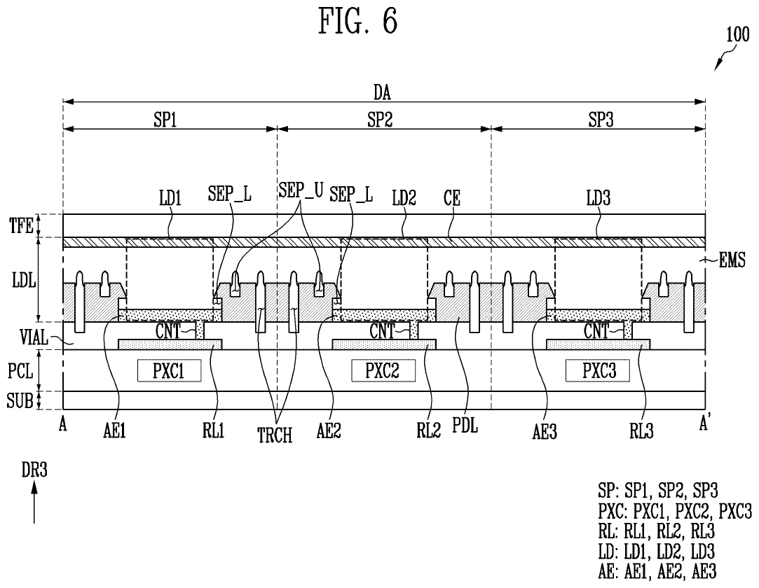

The pixel circuit layer PCL may be disposed on the substrate SUB. The substrate SUB and/or the pixel circuit layer PCL may include insulating layers and conductive patterns disposed between the insulating layers. The conductive patterns of the pixel circuit layer PCL may serve as at least some of circuit elements, lines, or the like. The conductive patterns may various conductive materials, but the disclosure is not limited to particular embodiment. The circuit elements may include a pixel circuit PXC (refer to FIG. 6) of each of the first to third sub-pixels SP1 to SP3. The pixel circuit may include and transistors and one or more capacitors.

The light-emitting element layer LDL may include anode electrodes AE, a pixel defining layer PDL, an emission structure EMS, and a cathode electrode CE.

The anode electrodes AE may be disposed on the pixel circuit layer PCL. The anode electrodes AE may be electrically connected to the circuit elements of the pixel circuit layer PCL.

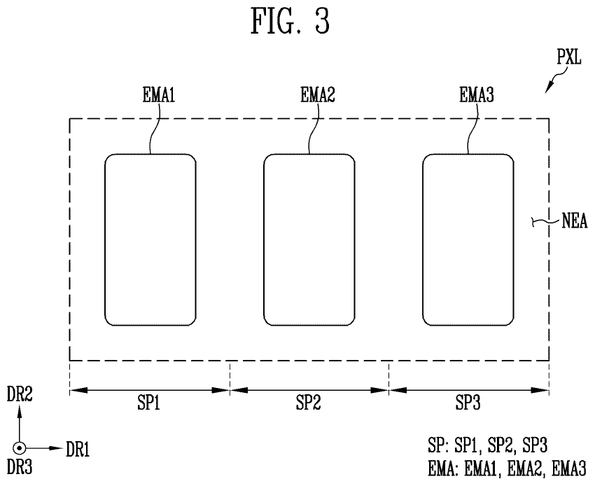

The pixel defining layer PDL may be disposed over the anode electrodes AE. The pixel defining layer PDL may define an opening OP exposing a portion of each of the anode electrodes AE. The opening OP of the pixel defining layer PDL may be understood as an emission area EMA (refer to FIG. 3) corresponding to each of the first to third sub-pixels SP1 to SP3.

The emission structure EMS may be disposed on the anode electrodes AE exposed by the openings OP of the pixel defining layer PDL. The emission structure EMS may include a light-emitting layer EML (refer to FIG. 8) which generates light, an electron transport unit ETU (refer to FIG. 8) which transports electrons, a hole transport unit HTU (refer to FIG. 8) which transports holes, or the like.

In an embodiment, the emission structure EMS fills the opening OP of the pixel defining layer PDL, and may be entirely disposed on the top of the pixel defining layer PDL. In other words, the emission structure EMS may extend throughout the first to third sub-pixels SP1 to SP3. At least some of the layers in the emission structure EMS may be cut or bent at boundaries between the first to third sub-pixels SP1 to SP3.

The cathode electrode CE may be disposed on the emission structure EMS. The cathode electrode CE may extend throughout the first to third sub-pixels SP1 to SP3. As such, the cathode electrode CE may be provided as a common electrode for the first to third sub-pixels SP1 to SP3.

The cathode electrode CE may be a thin metal layer having a thickness to a degree to which light emitted from the emission structure EMS may be transmitted therethrough. The cathode electrode CE may supply a cathode voltage to the emission structure EMS.

In some embodiments, the cathode electrode CE may be a thin metal layer having a thickness to a degree to which light emitted from the emission structure EMS may be transmitted therethrough. The cathode electrode CE may include or consist of a metal material to have a relatively thin thickness or include or consist of a transparent conductive material. In an embodiment, the cathode electrode CE may include at least one of various transparent conductive materials including indium tin oxide (“ITO”), indium zinc oxide (“IZO”), indium gallium zinc oxide (“IGZO”) aluminum zinc oxide (“AZO”), indium tin zinc oxide (“ITZO”), zinc oxide (ZnO), and tin oxide (SnO₂). In other embodiments, the cathode electrode CE may include at least one of silver (Ag), magnesium (Mg), and combinations thereof. However, the material of the cathode electrode CE is not limited thereto.

It may be understood that any one of the anode electrodes AE, a portion of the emission structure EMS, which overlaps therewith, and a portion of the cathode electrode CE, which overlaps therewith, constitute a light-emitting element LD. In other words, each of light-emitting elements of the first to third sub-pixels SP1 to SP3 may include an anode electrode AE, a portion of the emission structure EMS, which overlaps therewith, and a portion of the cathode electrode CE, which overlaps therewith. In each of the first to third sub-pixels SP1 to SP3, holes injected from the anode electrode AE and electrons injected from the cathode electrode CE may be transported into the light-emitting layer EML of the emission structure EMS to form excitons, and light may be generated when the excitons are changed from an excited state to a ground state. A luminance of the light may be determined according to an amount of current flowing through the light-emitting layer EML. A wavelength band of the generated light may be determined according to a configuration of the light-emitting layer EML.

The encapsulation layer TFE may be disposed over the cathode electrode CE. The encapsulation layer TFE may cover the light-emitting element layer LDL and/or the pixel circuit layer PCL. The encapsulation layer TFE may prevent oxygen and/or moisture from infiltrating into the light-emitting element layer LDL. In an embodiment, the encapsulation layer TFE may include a structure in which at least one inorganic layer and at least one organic layer are alternately stacked. In an embodiment, the inorganic layer may include silicon nitride, silicon oxide, silicon oxynitride (SiOₓN_{y}), or the like, for example. In an embodiment, the organic layer may include an organic insulating material such as acrylic resin, epoxy resin, phenolic resin, polyamide resin, polyimide resin, unsaturated polyester resin, polyphenylene resin, polyphenylenesulfide resin, or benzocyclobutene (“BCB”), for example. However, the materials of the organic layer and the inorganic layer of the encapsulation layer TFE are not limited thereto.

The optical functional layer OFL may be disposed on the encapsulation layer TFE. The optical functional layer OFL may include a color filter layer CFL and a lens array LA.

The color filter layer CFL may be disposed between the encapsulation layer TFE and the lens array LA. The color filter layer CFL may filter light emitted from the emission structure EMS, thereby selectively outputting light of a wavelength band or a color, which corresponds to each sub-pixel. The color filter layer CFL may include color filters CF respectively corresponding to the first to third sub-pixels SP1 to SP3. Each of the color filters CF may allow light having a wavelength band corresponding to a corresponding sub-pixel to pass therethrough. In an embodiment, a color filter corresponding to the first sub-pixel SP1 may allow light of a red color to pass therethrough, a color filter corresponding to the second sub-pixel SP2 may allow light of a green color to pass therethrough, and a color filter corresponding to the third sub-pixel SP3 may allow light of a blue color to pass therethrough, for example. According to light emitted from the emission structure EMS in each sub-pixel SP, at least some of the color filters CF may be omitted.

The lens array LA may be disposed on the color filter layer CFL. The lens array LA may include lenses LS respectively corresponding to the first to third sub-pixels SP1 to SP3. Each of the lenses LS may output light emitted from the emission structure EMS along an intended path, thereby improving light emission efficiency. The lens array LA may have a relatively high refractive index. In an embodiment, the lens array LA may have a refractive index higher than a refractive index of the overcoat layer OC, for example. In an embodiment, the lenses LS may include an organic material. In an embodiment, the lenses LS may include an acryl-based material. However, the material of the lenses LS is not limited thereto.

The overcoat layer OC may be disposed over the lens array LA. The overcoat layer OC may cover the optical functional layer OFL, the encapsulation layer TFE, the emission structure EMS, and/or the pixel circuit layer PCL. The overcoat layer OC may include various materials suitable for protecting lower layers thereof from foreign matters such as dust and moisture. In an embodiment, the overcoat layer OC may include at least one of an inorganic insulating layer and an organic insulating layer, for example. In an embodiment, the overcoat layer OC may include epoxy, for example, but the disclosure is not limited thereto. The overcoat layer OC may have a refractive index lower than a refractive index of the lens array LA.

The cover window CW may be disposed on the overcoat layer OC. The cover window CW may protect lower layers thereof. The cover window CW may have a refractive index higher than the refractive index of the overcoat layer OC. The cover window CW may include glass, but the disclosure is not limited thereto. In an embodiment, the cover window CW may be an encapsulation glass which protects components disposed thereunder, for example. In other embodiments, the cover window CW may be omitted.

FIG. 3 is a schematic plan view illustrating an embodiment of a pixel in accordance with the disclosure.

Referring to FIG. 3, a pixel PXL may include sub-pixels SP arranged in the first direction DR1. In an embodiment, the sub-pixels SP may include a first sub-pixel SP1, a second sub-pixel SP2, and a third sub-pixel SP3, which are arranged in the first direction DR1, for example. Emission areas EMA may include first to third emission areas EMA1 to EMA3.

The first sub-pixel SP1 may include the first emission area EMA1 and a non-emission area NEA at the periphery of the first emission area EMA1. The second sub-pixel SP2 may include the second emission area EMA2 and the non-emission area NEA at the periphery of the second emission area EMA2. The third sub-pixel SP3 may include the third emission area EMA3 and the non-emission area NEA at the periphery of the third emission area EMA3.

The first emission area EMA1 may be an area in which light is emitted from a portion (e.g., a first emission structure) of the emission structure EMS, which corresponds to the first sub-pixel SP1. The second emission area EMA2 may be an area in which light is emitted from a portion (e.g., a second emission structure) of the emission structure EMS, which corresponds to the second sub-pixel SP2. The third emission area EMA3 may be an area in which light is emitted from a portion (e.g., a third emission structure) of the emission structure EMS, which corresponds to the third sub-pixel SP3. As described with reference to FIG. 2, each emission area may be understood as an opening OP of the pixel defining layer PDL, which corresponds to each of the first to third sub-pixels SP1 to SP3.

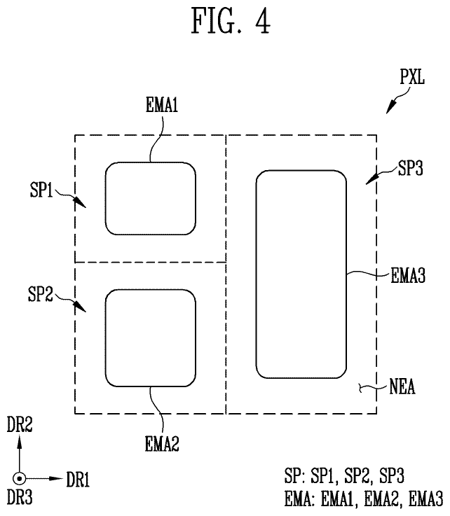

FIG. 4 is a schematic plan view illustrating another embodiment of a pixel in accordance with the disclosure.

Referring to FIG. 4, a first sub-pixel SP1 and a second sub-pixel SP2 may be arranged in the second direction DR2. A third sub-pixel SP3 may be disposed in the first direction DR1 with respect to each of the first and second sub-pixels SP1 and SP2.

The second sub-pixel SP2 may have an area larger than an area of the first sub-pixel SP1, and the third sub-pixel SP3 may have an area larger than the area of the second sub-pixel SP2. Accordingly, a second emission area EMA2 may have an area larger than an area of a first emission area EMA1, and a third emission area EMA3 may have an area larger than the area of the second emission area EMA2. However, the disclosure is not limited thereto. In an embodiment, the first and second sub-pixels SP1 and SP2 may substantially have the same area as each other, and the third sub-pixel SP3 may have an area larger than the area of each of the first and second sub-pixels SP1 and SP2, for example. As such, the areas of the first to third sub-pixels SP1 to SP3 may be variously modified in some embodiments.

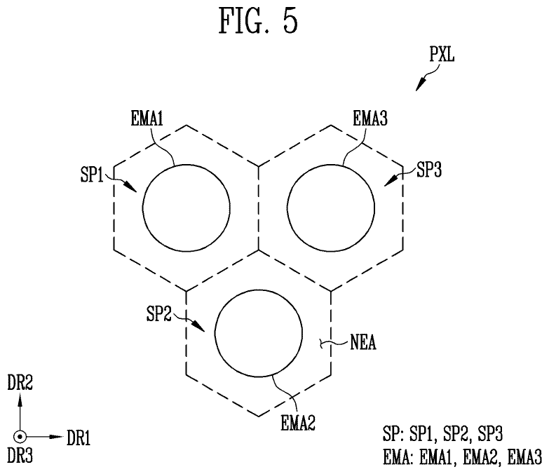

FIG. 5 is a schematic plan view illustrating another embodiment of a pixel in accordance with the disclosure.

Referring to FIG. 5, first to third sub-pixels SP1 to SP3 may have polygonal shapes when viewed in the third direction DR3. In an embodiment, the shapes of the first to third sub-pixels SP1 to SP3 may be hexagonal shapes as shown in FIG. 2, for example.

First to third emission areas EMA1 to EMA3 may have circular shapes when viewed in the third direction DR3. However, the disclosure is not limited thereto. In an embodiment, each of the first to third emission areas EMA1 to EMA3 may have a polygonal shape, for example.

The first and third sub-pixels SP1 and SP3 may be arranged in the first direction DR1. The second sub-pixel SP2 may be disposed in a direction (or diagonal direction) inclined by an acute angle, based on the second direction DR2, with respect to the first sub-pixel SP1.

The arrangements of the sub-pixels, which are shown in FIGS. 3 to 5, are merely illustrative, and the disclosure is not limited thereto. Each pixel PXL may include two or more sub-pixels SP, and the sub-pixels SP may be arranged in various manners. Each of the sub-pixels SP may have various shapes, and each of emission areas EMA of the sub-pixels SP may have various shapes.

A cross-sectional structure of the display device 100 in an embodiment of the disclosure will be described with reference to FIGS. 6 to 9.

FIG. 6 is a schematic cross-sectional view illustrating an embodiment of a display device in accordance with the disclosure. FIG. 6 is a schematic cutaway cross-sectional structure taken along line A-A′ shown in FIG. 1, and illustrates first to third sub-pixels SP1 to SP3 in a display area DA. For convenience of description, in FIG. 6, illustration of other layers on a light-emitting element layer LDL is omitted.

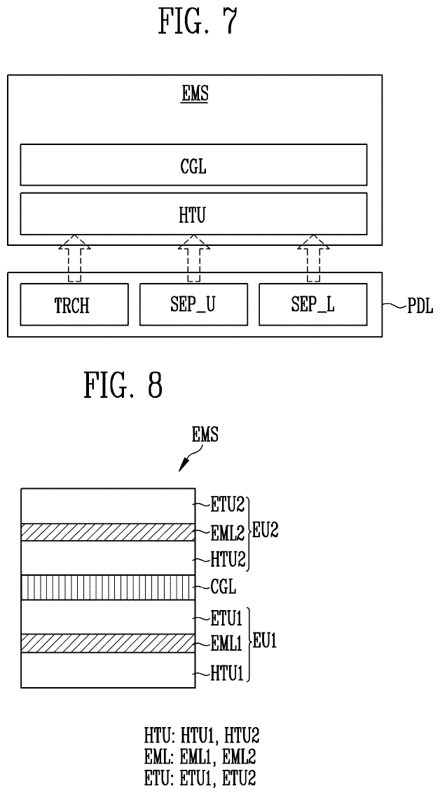

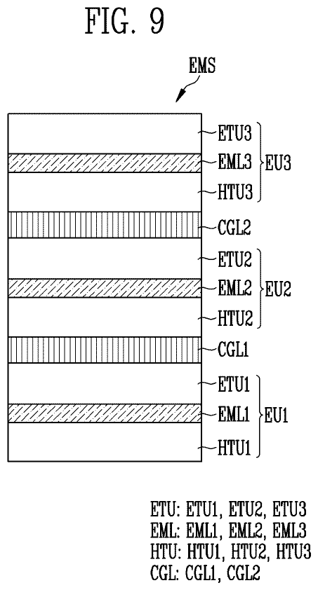

FIG. 7 is a schematic block diagram illustrating an embodiment of a relationship between a pixel defining layer and an emission structure in accordance with the disclosure. FIG. 8 is a schematic cross-sectional view illustrating an embodiment of an emission structure in accordance with the disclosure. FIG. 9 is a schematic cross-sectional view illustrating an embodiment of an emission structure in accordance with the disclosure.

Referring to FIGS. 6 to 9, a display device 100 may include a substrate SUB, and include layers on the substrate SUB in a display area DA.

The substrate SUB may include a silicon wafer substrate formed using a semiconductor process. The substrate SUB may include a semiconductor material suitable for forming circuit elements. In an embodiment, the semiconductor material may include silicon, germanium, and/or silicon-germanium, for example. The substrate SUB may be provided from a bulk wafer, an epitaxial layer, an SOI layer, an SeOI layer, or the like. In other embodiments, the substrate SUB may include a glass substrate. In still other embodiments, the substrate SUB may include a polyimide (“PI”) substrate.

The display device 100 may include a pixel circuit layer PCL.

The pixel circuit layer PCL may be disposed on the substrate SUB. The pixel circuit layer PCL may drive a light-emitting element LD, and include a pixel circuit PXC disposed in the display area DA. The pixel circuit layer PCL may include conductive layers and insulating layers, and the conductive layers may form the pixel circuit PXC. The pixel circuit PXC may include a first pixel circuit PXC1 which drives a first sub-pixel SP1 (e.g., a first light-emitting element LD1), a second pixel circuit PXC2 which drives a second sub-pixel SP2 (e.g., a second light-emitting element LD2), and a third sub-pixel PXC3 which drives a third sub-pixel SP3 (e.g., a third light-emitting element LD3).

The display device 100 may include a reflective layer RL.

The reflective layer RL may be disposed on the pixel circuit layer PCL in the display area DA, and overlap with an anode electrode AE in a plan view. The reflective layer RL may include a first reflective layer RL1 which is included in the first sub-pixel SP1 and overlaps with a first anode electrode AE1, a second reflective layer RL2 which is included in the second sub-pixel SP2 and overlaps with a second anode electrode AE2, and a third reflective layer RL3 which is included in the third sub-pixel SP3 and overlaps with a third anode electrode AE3.

The reflective layer RL may serve as a full mirror which reflects light emitted from an emission structure EMS toward a display surface (or a cover window CW (refer to FIG. 2)). At least a portion of the reflective layer RL may include metal materials suitable for reflecting light. In an embodiment, the metal materials may include at least one of aluminum (Al), silver (Ag), magnesium (Mg), platinum (Pt), palladium (Pd), gold (Au), nickel (Ni), neodymium (Nd), iridium (“IR”), chromium (Cr), titanium (Ti), and alloys of two or more materials selected therefrom, for example.

The reflective layer RL may be electrically connected to the pixel circuit PXC. In an embodiment, the first to third reflective layers RL1 to RL3 may be electrically connected to the first to third pixel circuits PXC1 to PXC3, respectively, for example. In some embodiments, the reflective layer RL may be a bridge structure to which an anode voltage of the light-emitting element LD is supplied.

The display device 100 may include an inter-insulating layer VIAL.

The inter-insulating layer VIAL may be disposed on the pixel circuit layer PCL. In some embodiments, the inter-insulating layer VIAL may be a via layer. In an embodiment, a contact portion CNT may be formed in the inter-insulating layer VIAL, for example. The inter-insulating layer VIAL may cover the reflective layers RL, and be a planarization layer. The inter-insulating layer VIAL may include various organic materials. However, the disclosure is not limited thereto. In an embodiment, the inter-insulating layer VIAL may include an inorganic material, for example.

The display device 100 may include a light-emitting element layer LDL. The display device 100 (or the light-emitting element layer LDL) may include the anode electrode AE, a pixel defining layer PDL, the emission structure EMS, and a cathode electrode CE.

The anode electrode AE may be disposed on the inter-insulating layer VIAL in the display area DA. The anode electrode AE may be electrically connected to the reflective layer RL through the contact portion CNT penetrating the inter-insulating layer VIAL.

The anode electrode AE may include the first anode electrode AE1 included in the first sub-pixel SP1 to form the first light-emitting element LD1, the second anode electrode AE2 included in the second sub-pixel SP2 to form the second light-emitting element LD2, and the third anode electrode AE3 included in the third sub-pixel SP3 to form the third light-emitting element LD3.

The anode electrode AE may include at least one of various transparent conductive materials including ITO, IZO, zinc oxide (ZnOₓ), IGZO, and ITZO. However, the material of the anode electrode AE is not limited thereto. In an embodiment, the anode electrode AE may include titanium nitride, for example.

The pixel defining layer PDL may be disposed on the inter-insulating layer VIAL in the display area DA. The pixel defining layer PDL may be next (adjacent) to the anode electrode AE. The pixel defining layer PDL may be next (adjacent) (e.g., directly next (adjacent)) to a side surface of the anode electrode AE, and expose a portion of the anode electrode AE. In some embodiments, the pixel defining layer PDL may not in contact with an upper surface of the anode electrode AE. The upper surface may be a top surface.

The pixel defining layer PDL may include an inorganic material. In an embodiment, the pixel defining layer PDL may include at least one of silicon oxide (SiₓO_{y}) and silicon nitride (SiₓN_{y}), for example. However, the disclosure is not limited thereto.

The pixel defining layer PDL may have a single-layer structure. In some embodiments, the pixel defining layer PDL may have a multi-layer structure.

The pixel defining layer PDL may include separating structures capable of reducing a lateral leakage risk between neighboring (adjacent) sub-pixels SP. In an embodiment, the pixel defining layer PDL may define a trench TRCH, further define an upper separator SEP_U, and further define a lower separator SEP_L, for example.

The trench TRCH may at least partially or entirely penetrate the pixel defining layer PDL. In some embodiments, the trench TRCH may partially penetrate a portion of the inter-insulating layer VIAL. In an embodiment, the trench TRCH may penetrate at least a portion of the pixel defining layer PDL, for example.

The trench TRCH may include a void. As the trench TRCH forms the void, at least a portion of the emission structure EMS formed to cover the trench TRCH may be cut or bent. In an embodiment, at least a portion of layers commonly formed in the first to third sub-pixels SP1 to SP3 among a plurality of layers included in the emission structure EMS may be cut by the trench TRCH, for example. In an embodiment, at least a portion of layers (e.g., a charge generation layer CGL and/or a portion of a hole transport unit HTU) commonly formed in the first to third sub-pixels SP1 to SP3 among the plurality of layers included in the emission structure EMS may be cut by the trench TRCH, for example.

The number of trenches TRCH is not limited to a particular embodiment. In some embodiments, the trench TRCH may include two trenches disposed between neighboring (adjacent) sub-pixels SP.

The lower separator SEP_L may have an undercut structure of the pixel defining layer PDL. The lower separator SEP_L may be defined in an edge of the upper surface of the anode electrode AE. The lower separator SEP_L may be defined between the anode electrode AE and a portion of the pixel defining layer PDL. As the lower separator SEP_L forms the undercut structure, at least a portion of the emission structure EMS formed to cover the lower separator SEP_L may be cut or bent. In an embodiment, at least a portion of layers (e.g., the charge generation layer CGL and/or a portion of the hole transport unit HTU) commonly formed in the first to third sub-pixels SP1 to SP3 among the plurality of layers included in the emission structure EMS may be cut by the lower separator SEP_L, for example.

The upper separator SEP_U may be a protruding structure or a recessed structure. The upper separator SEP_U may be defined in an upper surface of the pixel defining layer PDL. As the upper separator SEP_U forms the protruding structure or the recessed structure, at least a portion of the emission structure EMS formed to cover the upper separator SEP_U may be cut or bent. In an embodiment, at least a portion of layers (e.g., the charge generation layer CGL and/or a portion of the hole transport unit HTU) commonly formed in the first to third sub-pixels SP1 to SP3 among the plurality of layers included in the emission structure EMS may be cut by the upper separator SEP_U, for example.

The upper separator SEP_U may have a structure different from a structure of the trench TRCH. Since common layers of the emission structure EMS disposed throughout the sub-pixels SP may be cut in a different form, the common layers are more thoroughly cut, so that a risk of lateral leakage may be remarkably reduced. In an embodiment, the upper separator SEP_U may have a protruding structure unlike the trench TRCH, or have a concave structure having a depth different from a depth of the trench TRCH, for example. In an embodiment, the upper separator SEP_U may have a trench structure having a depth lower than the depth of the trench TRCH, for example. In an alternative embodiment, in another embodiment, the upper separator SEP_U may have a concave structure having a width different from a width of the trench TRCH.

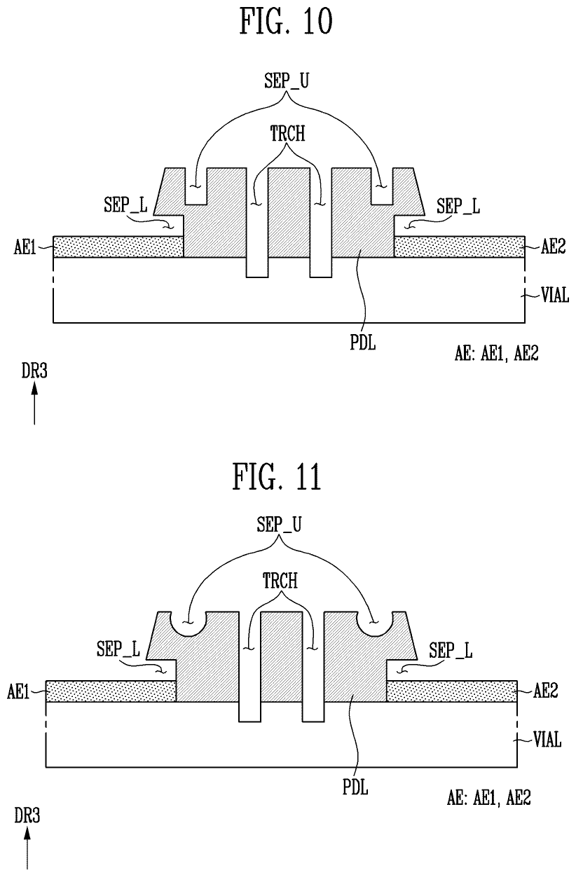

Various embodiments of the lower separator SEP_L and the upper separator SEP_U in the embodiment of the disclosure will be described later with reference to drawings from FIG. 10.

The emission structure EMS may be disposed on the anode electrode AE exposed by the pixel defining layer PDL in the display area DA, and be disposed throughout the first to third sub-pixels SP1 to SP3. As described above, the emission structure EMS may be at least partially cut or bent in a boundary area by the trench TRCH. Accordingly, the risk of lateral leakage may be reduced, and the sub-pixels SP may have operational characteristics having improved reliability.

The emission structure EMS may include a multi-layer structure electrically connected between the anode electrode AE and the cathode electrode CE.

In some embodiments (refer to FIG. 8), the emission structure EMS may have a tandem structure in which first and second light-emitting units EU1 and EU2 are stacked. The emission structure EMS may be configured substantially identically in each of the first to third light-emitting elements LD1, LD2, and LD3.

The emission structure EMS may include a hole transport unit HTU, a light-emitting layer EML, and an electron transport unit ETU, and further include a charge generation layer CGL. Each layer forming the emission structure EMS may include one organic material, and further include a compound including or consisting of metal, an inorganic material such as a quantum dot, or the like in some embodiments.

The hole transport unit HTU may include a multi-layer structure having a plurality of layers including different materials from each other. In an embodiment, the hole transport unit HTU may include a hole injection layer and a hole transport layer, and further include a light-emitting auxiliary layer, an electron blocking layer, or the like in some embodiments.

The light-emitting layer EML may include a material capable of emitting light of a color. The light-emitting layer EML may include a host and a dopant. The host of the light-emitting layer EML is a light-emitting material capable of capturing carriers (electrons and holes) for generating light, and may induce excitons to be efficiently generated. The dopant of the light-emitting layer EML may include a phosphorescent dopant and a fluorescent dopant. In some embodiments, embodiments of the dopant are not particularly limited. In some embodiments, the dopant may include an organic material. The dopant may also include a metal complex or the like.

The electron transport unit ETU may include a multi-layer structure having a plurality of layers including different materials from each other. The electron transport unit ETU may include an electron injection layer and an electron transport layer. In some embodiments, the electron transport unit ETU may further include an electron buffer layer, a hole blocking layer, or the like.

The first light-emitting unit EU1 may include a first light-emitting layer EML1, a first electron transport unit ETU1, and a first hole transport unit HTU1. The first light-emitting layer EML1 may be disposed between the first electron transport unit ETU1 and the first hole transport unit HTU1. The second light-emitting unit EU2 may include a second light-emitting layer EML2, a second electron transport unit ETU2, and a second hole transport unit HTU2. The second light-emitting layer EML2 may be disposed between the second electron transport unit ETU2 and the second hole transport unit HTU2.

A connection layer, which may be provided in the form of a charge generation layer CGL, may be disposed between the first light-emitting unit EU1 and the second light-emitting unit EU2 to connect the first light-emitting unit EU1 and the second light-emitting unit EU2 to each other. In an embodiment, the charge generation layer CGL may have a stacked structure of a p-dopant layer and an n-dopant layer. In an embodiment, the p-dopant layer may include a p-type dopant such as 1,4,5,8,9,11-Hexaazatriphenylenehexacarbonitrile (“HAT-CN”), tetracyanoquinodimethane (“TCNQ”) or 2-(7-Dicyanomethylene-1,3,4,5,6,8,9,10-octafluoro-7H-pyren-2-ylidene)-malononitrile (“NDP-9”), and the n-dopant layer may include an alkali metal, an alkali earth metal, a lanthanide-based metal, or any combination thereof, for example. However, the disclosure is not limited thereto.

In an embodiment, the first light-emitting layer EML1 and the second light-emitting layer EML2 may generate lights of different colors. Lights respectively emitted from the first light-emitting layer EML1 and the second light-emitting layer EML2 may be mixed together, to be viewed as white light. In an embodiment, the first light-emitting layer EML1 may generate light of a blue color, and the second light-emitting layer EML2 may generate light of a yellow color, for example. In an embodiment, the second light-emitting layer EML2 may include a structure in which a first sub-light-emitting layer which generates light of a red color and a second sub-light-emitting layer which generates light of a green color are stacked. The light of the red color and the light of the green color may be mixed together to provide the light of the yellow color. An intermediate layer which performs a function of transporting holes and/or a function of blocking transportation of electrodes may be further disposed between the first and second sub-light-emitting layers.

In some embodiments, (refer to FIG. 9), an emission structure EMS may a tandem structure in which first to third light-emitting units EU1 to EU3 are stacked. The emission structure EMS may be configured substantially identically in each of the first to third light-emitting elements LD1 to LD3 shown in FIG. 6.

The first light-emitting unit EU1 may include a first light-emitting layer EML1, a first electron transport unit ETU1 and a first hole transport unit HTU1. The first light-emitting layer EML1 may be disposed between the first electron transport unit ETU1 and the first hole transport unit HTU1. The second light-emitting unit EU2 may include a second light-emitting layer EML2, a second electron transport unit ETU2, and a second hole transport unit HTU2. The second light-emitting layer EML2 may be disposed between the second electron transport unit ETU2 and the second hole transport unit HTU2. The third light-emitting unit EU3 may include a third light-emitting layer EML3, a third electron transport unit ETU3, and a third hole transport unit HTU3. The third light-emitting layer EML3 may be disposed between the third electron transport unit ETU3 and the third hole transport unit HTU3.

A first charge generation layer CGL1 may be disposed between the first light-emitting unit EU1 and the second light-emitting unit EU2. A second charge generation layer CGL2 may be disposed between the second light-emitting unit EU2 and the third light-emitting unit EU3.

In an embodiment, the first to third light-emitting layers EML1 to EML3 may generate lights of different colors. Lights respectively emitted from the first to third light-emitting layers EML1 to EML3 may be mixed together, to be viewed as white light. In an embodiment, the first light-emitting layer EML1 may generate light of a blue color, the second light-emitting layer EML2 may generate light of a green color, and the third light-emitting layer EML3 may generate light of a red color, for example.

The cathode electrode CE may be disposed on the emission structure EMS in the display area DA. The cathode electrode CE may be commonly provided in the first to third sub-pixels SP1 to SP3. The cathode electrode CE may serve as a half mirror which allows light emitted from the emission structure EMS to be partially transmitted therethrough and to be partially reflected therefrom.

In some embodiments, the encapsulation layer TFE may encapsulate the light-emitting element layer LDL (e.g., the light-emitting element LD). Accordingly, the light-emitting elements LD may be appropriately protected from an external impurity.

Structures of a pixel defining layer PDL in an embodiment of the disclosure will be described with reference to FIGS. 10 to 17. For convenience of description, descriptions of portions overlapping with the above-described portions will be simplified or will not be repeated.

FIGS. 10 to 17 are schematic cross-sectional views illustrating an embodiment of an anode electrode and a pixel defining layer in accordance with the disclosure. For convenience of description, in FIGS. 10 to 17, illustration of other components except an inter-insulating layer VIAL, an anode electrode AE, and a pixel defining layer PDL is omitted. In addition, FIGS. 10 to 17 illustrate sub-pixels SP next (adjacent) to each other so as to described structural features of the pixel defining layer PDL. In an embodiment, FIGS. 10 to 17 schematically illustrate first and second sub-pixels SP1 and SP2 next (adjacent) to each other, for example.

First, a pixel defining layer PDL in an embodiment of the disclosure will be described with reference to FIG. 10. Referring to FIG. 10, the pixel defining layer PDL in the embodiment of the disclosure may be next (adjacent) to a first anode electrode AE1 and a second anode electrode AE2 in a lateral direction.

The pixel defining layer PDL may define a lower separator SEP_L having an undercut structure. The lower separator SEP_L may be a cavity, and have a structure in which a lower portion of the pixel defining layer PDL is recessed from a center of the anode electrode AE. The lower separator SEP_L may expose an upper surface of the anode electrode AE, and accordingly, the upper surface of the anode electrode AE may not in direct contact with the pixel defining layer PDL.

A trench TRCH may entirely penetrate the pixel defining layer PDL, and partially penetrate a portion of the inter-insulating layer VIAL.

An upper separator SEP_U may partially penetrate the pixel defining layer PDL, and may not entirely penetrate the pixel defining layer PDL. In an embodiment, a depth of the upper separator SEP_U may be smaller than a depth of the trench TRCH, for example.

The upper separator SEP_U may have a trench-type structure. The upper separator SEP_U may form a concave structure. The upper separator SEP_U may include a cavity.

The upper separator SEP_U may have a polygonal cross-sectional profile. In an embodiment, the upper separator SEP_U may have a quadrangular section, for example. In an embodiment, the upper separator SEP_U may be a manufactured using a dry etching process, for example.

One upper separator SEP_U may be defined in a side of the trench TRCH, and another upper separator SEP_U may be defined in an opposite side of the trench TRCH opposite to the side of the trench TRCH.

As described above, the lower separator SEP_L and the upper separator SEP_U are further defined in addition to the trench TRCH, and thus the lateral leakage risk between neighboring (adjacent) sub-pixels SP may be remarkably reduced.

Next, a pixel defining layer PDL in an embodiment of the disclosure will be described with reference to FIG. 11. Referring to FIG. 11, the pixel defining layer PDL in an embodiment of the disclosure is different from the pixel defining layer PDL described on with reference to FIG. 10, in that a cross-sectional shape of an upper separator SEP_U has a relatively round shape.

The pixel defining layer PDL may define a lower separator SEP_L having an undercut structure, and the upper separator SEP_U may have a relatively curved cross-sectional profile. In an embodiment, the upper separator SEP_U may have a semicircular section, for example. In an embodiment, the upper separator SEP_U may be a manufactured using a wet etching process, for example.

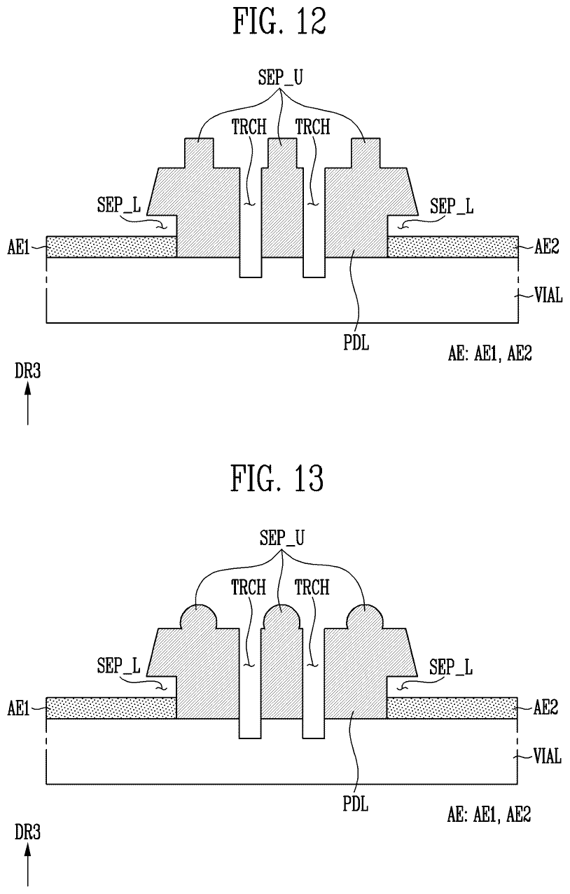

Next, a pixel defining layer PDL in an embodiment of the disclosure will be described with reference to FIG. 12. Referring to FIG. 12, the pixel defining layer PDL in the embodiment of the disclosure is different from the pixel defining layer PDL described on with reference to FIG. 10, in that an upper separator SEP_U has a relatively protruding structure having a polygonal section on an upper surface of the pixel defining layer PDL.

The upper separator SEP_U may have a protruding structure. The upper separator SEP_U may form a convex structure.

The pixel defining layer PDL may define a lower separator SEP_L having an undercut structure, and the upper separator SEP_U may have a polygonal section profile. In an embodiment, the upper separator SEP_U may have a quadrangular section, for example. In an embodiment, the upper separator SEP_U may be a manufactured using a dry etching process, for example.

In some embodiments, a portion of upper separators SEP_U may be defined between trenches TRCH spaced apart from each other. Another portion of the upper separators SEP_U may be defined between the trench TRCH and the lower separator SEP_L. Accordingly, with respect to a direction toward a second anode electrode AE from a first anode electrode AE2, a first lower separator, a first upper separator, a first trench, a second upper separator, a second trench, a third upper separator, and a second lower separator may be sequentially disposed or defined.

Next, a pixel defining layer PDL in an embodiment of the disclosure will be described with reference to FIG. 13. Referring to FIG. 13, the pixel defining layer PDL in the embodiment of the disclosure is different from the pixel defining layer PDL described on with reference to FIG. 10, in that an upper separator SEP_U has a relatively protruding structure having a relatively round outer surface at an upper surface of the pixel defining layer PDL.

The upper separator SEP_U may have a protruding structure. The upper separator SEP_U may form a convex structure.

The pixel defining layer PDL may define a lower separator SEP_L having an undercut structure, and the upper separator SEP_U may have a cross-sectional profile having a relatively round outer surface. In an embodiment, the upper separator SEP_U may have a semicircular section, for example. In an embodiment, the upper separator SEP_U may be a manufactured using a wet etching process, for example.

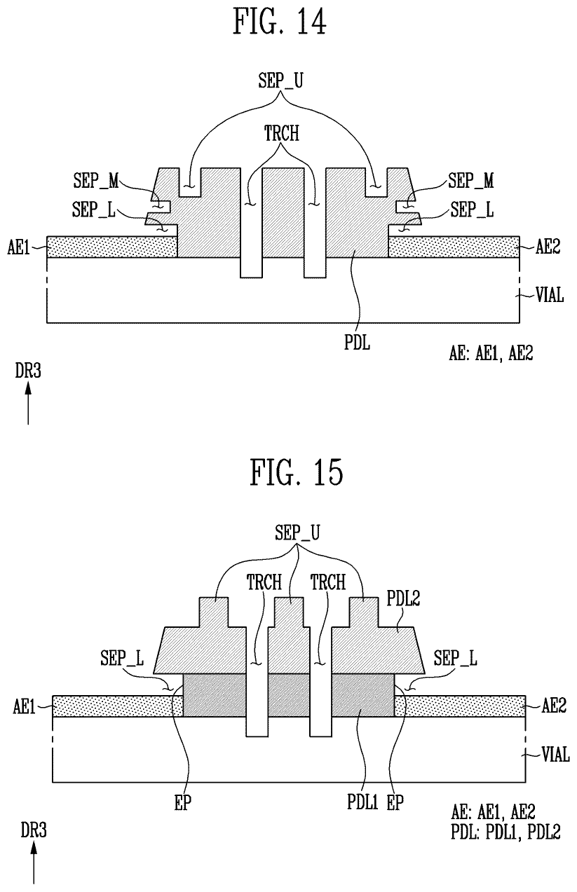

Next, a pixel defining layer PDL in an embodiment of the disclosure will be described with reference to FIG. 14. Referring to FIG. 14, the pixel defining layer PDL in the embodiment of the disclosure is different from the pixel defining layer PDL described on with reference to FIG. 10, in that the pixel defining layer PDL in the embodiment of the disclosure further defines an intermediate separator SEP_M.

The pixel defining layer PDL in the embodiment of the disclosure may define a lower separator SEP_L having an undercut structure, define an upper separator SEP_U having a trench-type structure (e.g., a trench structure in which a trench is defined), and further define the intermediate separator SEP_M on the lower separator SEP_L.

The intermediate separator SEP_M may be defined in a side surface of the pixel defining layer PDL. The intermediate separator SEP_M may overlap with the anode electrode AE and the lower separator SEP_L in a plan view.

The intermediate separator SEP_M may be a cavity in which a portion of the side surface of the pixel defining layer PDL is recessed. When the emission structure EMS is disposed on the side surface of the pixel defining layer PDL, at least a portion (e.g., the charge generation layer CGL, the hole transport unit HTU, or the like) of the emission structure may be cut by the intermediate separator SEP_M at the side surface of the pixel defining layer PDL.

Accordingly, at least a portion of the emission structure EMS may be cut by the trench TRCH, the upper separator SEP_U, the lower separator SEP_L, and the intermediate separator SEP_M, and the lateral leakage risk may be reduced.

Next, a pixel defining layer PDL in an embodiment of the disclosure will be described with reference to FIG. 15. Referring to FIG. 15, the pixel defining layer PDL in the embodiment of the disclosure is different from the pixel defining layer PDL described on with reference to FIG. 12, in that the pixel defining layer PDL in the embodiment of the disclosure includes a first pixel defining layer PDL1 and a second pixel defining layer PDL2.

The pixel defining layer PDL in the embodiment of the disclosure may define a lower separator SEP_L having an undercut structure, define an upper separator SEP_U having a protruding structure, and include the first pixel defining layer PDL1 forming a lower portion of the pixel defining layer PDL and the second pixel defining layer PDL1 forming an upper portion of the pixel defining layer PDL.

The first pixel defining layer PDL1 may be disposed on the inter-insulating layer VIAL. The first pixel defining layer PDL1 may be disposed between the first anode electrode AE1 and the second anode electrode AE2. A side surface EP of the first pixel defining layer PDL1 may be next (adjacent) (e.g., directly next (adjacent)) to a side surface of the first anode electrode AE1. Another side surface EP of the pixel defining layer PDL1 may be next (adjacent) (e.g., directly next (adjacent)) to a side surface of the second anode electrode AE2.

The first pixel defining layer PDL1 may not cover the upper surface of the anode electrode AE. The first pixel defining layer PDL1 may entirely expose the upper surface of the anode electrode AE. The first pixel defining layer PDL1 may have a thickness thicker than a thickness of the anode electrode AE. The first pixel defining layer PDL1 may have a width narrower than a width of the second pixel defining layer PDL2. The first pixel defining layer PDL1 may be directly next (adjacent) to the lower separator SEP_L.

The second pixel defining layer PDL2 may be disposed on the first pixel defining layer PDL1. A portion of the second pixel defining layer PDL2 may overlap with the lower separator SEP_L and the anode electrode AE in a plan view. The upper separator SEP_U may be defined in an upper surface of the second pixel defining layer PDL2.

A trench TRCH may penetrate the second pixel defining layer PDL2, the first pixel defining layer PDL1, and a portion of the inter-insulating layer VIAL.

In some embodiments, the first and second pixel defining layers PDL1 and PDL2 may include different material. When an etching process for patterning the pixel defining layer PDL is performed, an amount with which the first pixel defining layer PDL1 is etched and an amount with which the second pixel defining layer PDL2 is etched may be different from each other, and the first pixel defining layer PDL1 may be patterned to have a width narrower than the width of the second pixel defining layer PDL2. Accordingly, the lower separator SEP_L surrounded by the first pixel defining layer PDL, the second pixel defining layer PDL2, and the anode electrode AE may be formed without performing any additional process.

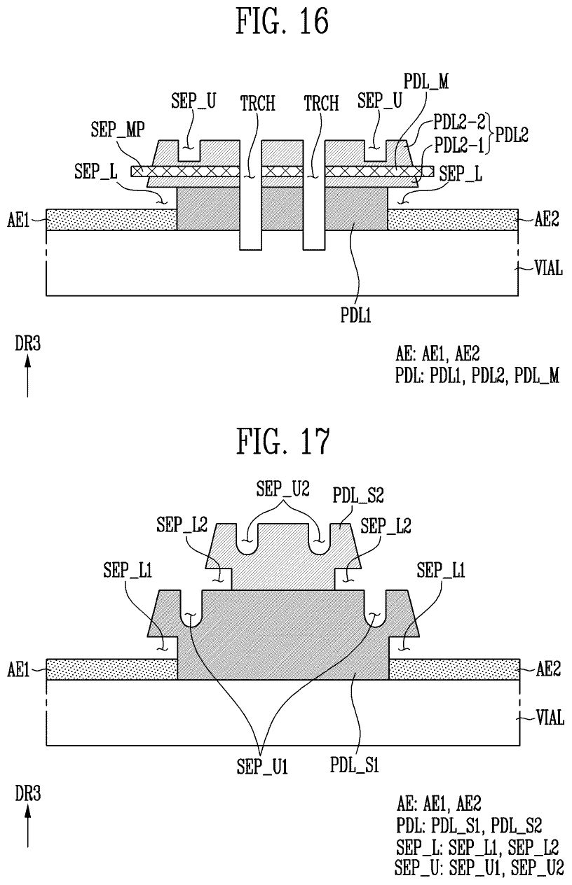

Next, a pixel defining layer PDL in an embodiment of the disclosure will be described with reference to FIG. 16. Referring to FIG. 16, the pixel defining layer PDL in the embodiment of the disclosure is different from the pixel defining layer PDL described on with reference to FIG. 15, in that an upper separator SEP_U has a trench-type structure, and the pixel defining layer PDL in the embodiment of the disclosure includes an intermediate pixel defining layer PDL_M.

The pixel defining layer PDL in the embodiment of the disclosure may define a lower separator SEP_L having an undercut structure, define the upper separator SEP_U having a trench-type structure, and include the intermediate pixel defining layer PDL_M which has a width larger than a width of each of first and second pixel defining layers PDL1 and PDL2 and defines an intermediate protrusion separator SEP_MP.

The second pixel defining layer PDL2 may include a (2-1)th pixel defining layer PDL2-1 disposed between the first pixel defining layer PDL1 and the intermediate pixel defining layer PDL_M and a (2-2)th pixel defining layer PDL2-2 disposed on the intermediate pixel defining layer PDL_M. In some embodiments, the upper separator SEP_U may be defined in the (2-2)th pixel defining layer PDL2-2, and may not penetrate the intermediate separator SEP_M. A trench TRCH may penetrate the (2-1)th pixel defining layer PDL2-1, the intermediate separator SEP_M, the (2-2)th pixel defining layer PDL2-2, the first pixel defining layer PDL, and a portion of the inter-insulating layer VIAL.

The (2-1)th pixel defining layer PDL2-1 and the (2-2)th pixel defining layer PDL2-2 may be spaced apart from each other in a thickness direction of the substrate SUB (e.g., the third direction DR3).

The (2-1)th pixel defining layer PDL2-1 and the (2-2)th pixel defining layer PDL2-2 may include the same material as each other. The first and second pixel defining layers PDL1 and PDL2 may include different material, and the second pixel defining layer PDL2 and the intermediate pixel defining layer PDL_M may include different materials from each other. When an etching process for patterning the pixel defining layer PDL is performed, an amount with which the second pixel defining layer PDL2 is etched and an amount with which the intermediate separator SEP_M is etched may be different from each other, and the second pixel defining layer PDL2 may be patterned to have a width narrower than a width of the intermediate pixel defining layer PDL_M. Accordingly, the intermediate protrusion separator SEP_MP capable of cutting at least a portion of the emission structure EMS at a side surface of the pixel defining layer PDL may be defined without performing any additional process.

Next, a pixel defining layer PDL in an embodiment of the disclosure will be described with reference to FIG. 17. Referring to FIG. 17, the pixel defining layer PDL in the embodiment of the disclosure is different from the pixel defining layer PDL described on with reference to FIG. 10, in that the pixel defining layer PDL in the embodiment of the disclosure does not define the trench TRCH and includes first and second pixel defining structures PDL_S1 and PDL_S2.

The pixel defining layer PDL in the embodiment of the disclosure may include the first and second pixel defining structures PDL_S1 and PDL_S2 each including a lower separator SEP_L and an upper separator SEP_U.

The lower separator SEP_L may include a first lower separator SEP_L1 and a second lower separator SEP_L2. The upper separator SEP_U may include a first upper separator SEP_U1 and a second upper separator SEP_U2.

The first pixel defining structure PDL_S1 may have structure similar to the structure of the pixel defining layer PDL described on with reference to FIG. 10. In an embodiment, first pixel defining structure PDL_S1 does not define the trench TRCH, and may define a first lower separator SEP_L1 having an undercut structure and define a first upper separator SEP_U1 partially penetrating the first pixel defining structure PDL_S1, for example.

The second pixel defining structure PDL_S2 may be disposed on the first pixel defining structure PDL_S1. In some embodiments, the second pixel defining structure PDL_S2 may include a material different from a material of the first pixel defining structure PDL_S1. However, the disclosure is not limited thereto.

The second pixel defining structure PDL_S2 may have a structure similar to the structure of the first pixel defining structure PDL_S1. The second pixel defining structure PDL_S2 may have a section size smaller than a section size of the first pixel defining structure PDL_S1, and define a second lower separator SEP_L2 and a second upper separator SEP_U2, similarly to the first pixel defining structure PDL_S1. In an embodiment, the second pixel defining structure PDL_S2 does not define the trench TRCH, and may define the second lower separator SEP_L2 having an undercut structure and define the second upper separator SEP_U2 partially penetrating the second pixel defining structure PDL_S2, for example.

In some embodiments, the second lower separator SEP_L2 may expose a portion of an upper surface of the first pixel defining structure PDL_S1. The second lower separator SEP_L2 may be next (adjacent) to the first upper separator SEP_U1.

In some embodiments, when the emission structure EMS is disposed through the sub-pixels SP, at least a portion of the emission structure EMS may be cut by the first lower separator SEP_L1, the first upper separator SEP_U1, the second lower separator SEP_L2, and the second upper separator SEP_U2, and thus a risk of lateral leakage may be reduced. In addition, since the first lower separator SEP_L1, the first upper separator SEP_U1, the second lower separator SEP_L2, and the second upper separator SEP_U2 have different structures from each other, the common layers of the emission structure EMS may be thoroughly cut complementarily by the first lower separator SEP_L1, the first upper separator SEP_U1, the second lower separator SEP_L2, and the second upper separator SEP_U2.

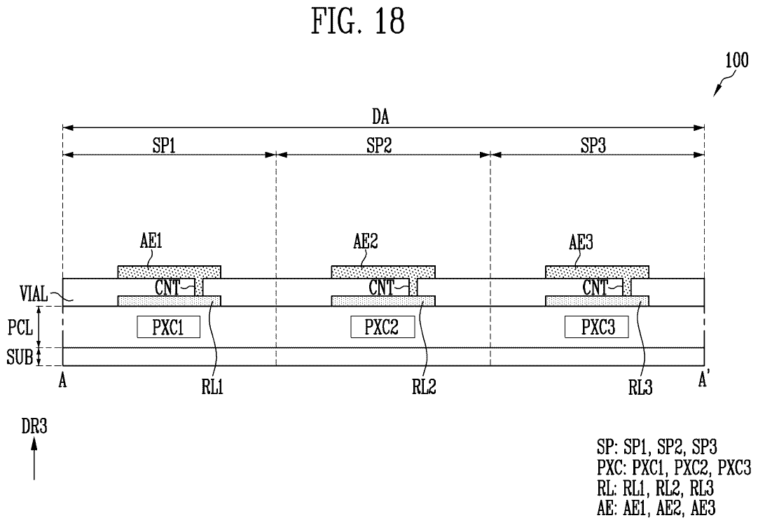

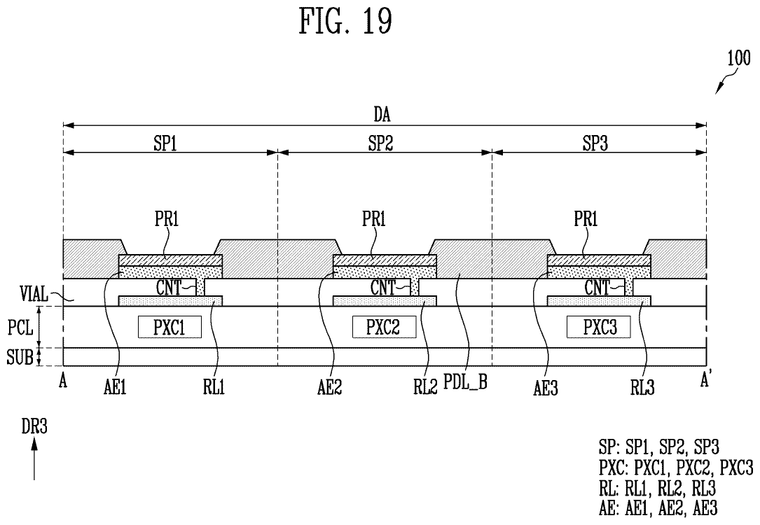

A method of manufacturing a display device 100 in an embodiment of the disclosure will be described with reference to FIGS. 18 to 29. For convenience of description, descriptions of portions overlapping with the above-described portions will be simplified or will not be repeated.

First, a method of manufacturing a display device 100 including a lower separator SEP_L and an upper separator SEP_U, in which the upper separator SEP_U has a trench-type structure, will be described with reference to FIGS. 18 to 29.

FIGS. 18 to 23 are schematic cross-sectional views illustrating an embodiment of process steps of a method of manufacturing a display device in accordance with the disclosure. For convenience of description, FIGS. 18 to 23 are illustrated based on the cross-sectional structure described on with reference to FIG. 6.

Referring to FIG. 18, pixel circuits PXC, reflective layers RL, and anode electrodes AE may be patterned on a substrate SUB.

In some embodiments, a conductive layer or an insulating layer on the substrate SUB may be formed based on an ordinary process for manufacturing a semiconductor device. In an embodiment, the conductive layer or the insulating layer on the substrate SUB may be formed through a photolithography process, be etched through various processes (wet etching, dry etching, or the like), and be deposited through various processes (sputtering, chemical vapor deposition, or the like), for example. However, the disclosure is not necessarily limited to a particular embodiment.

In addition, a photoresist layer in this specification may include a negative-type photoresist. However, the disclosure is not necessarily limited thereto. Hereinafter, for convenience of description, an embodiment in which the photoresist layer includes a negative-type photoresist will be mainly described.

In this phase, a pixel circuit layer PCL may be formed by patterning first to third pixel circuits PXC1 to PXC3 on the substrate SUB. First to third reflective layers RL1 to RL3 may be patterned on the pixel circuit layer PCL, an inter-insulating layer VIAL may be formed on the pixel circuit layer PCL, and first to third anode electrodes AE1 to AE3 electrically connected to the first to third reflective layers RL1 to RL3 through contact portions CNT may be patterned on the inter-insulating layer VIAL.

Referring to FIG. 19, a first photoresist layer PR1 may be patterned on the anode electrodes AE, and a base pixel defining layer PDL_B may be patterned.

In this phase, the first photoresist layer PR1 may be patterned to cover an entirety of upper surfaces of the anode electrodes AE and not to cover side surfaces of the anode electrode AE.

In this phase, the base pixel defining layer PDL_B may be patterned after the first photoresist layer PR1 is patterned. The base pixel defining layer PDL_B may cover a side surface of each of the first photoresist layer PR1 and the anode electrodes AE and a portion of an upper surface of the first photoresist layer PR1. The base pixel defining layer PDL_B may expose the upper surface of the first photoresist layer PR1.

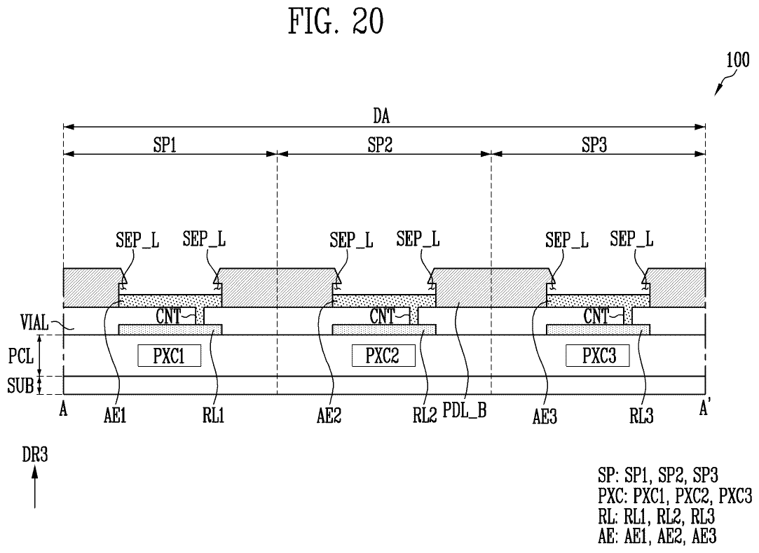

Referring to FIG. 20, the first photoresist layer PR1 may be removed, and a lower separator SEP_L having an undercut structure may be defined.

In some embodiments, since the base pixel defining layer PDL_B covers the portion of the upper surface of the first photoresist layer PR1, the undercut structure may be formed in the base pixel defining layer PDL_B when the first photoresist layer PR1 is removed. In an embodiment, the first photoresist layer PR1 may be removed using a process such as ashing, for example. Accordingly, the lower separator SEP_L having the undercut structure may be defined. Thus, a risk that the anode electrode AE will be damaged by an etching process may be reduced.

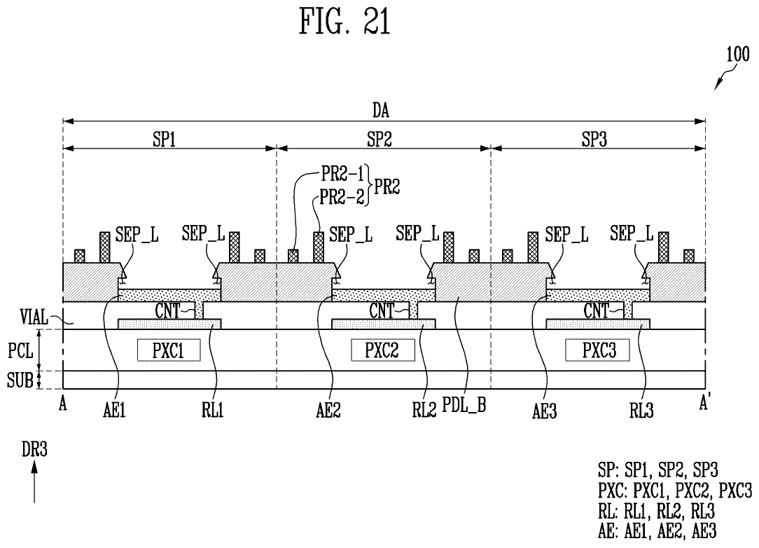

Referring to FIG. 21, a second photoresist layer PR2 may be patterned on an upper surface of the base pixel defining layer PDL_B.

In this phase, the second photoresist layer PR2 may be patterned using a photomask including a full-tone portion, a half-tone portion, and a blocking portion. The full-tone portion may allow light to be transmitted therethrough in a light exposure process. The half-tone portion may allow a portion of light and/or light to be partially transmitted therethrough in the light exposure process. The blocking portion may block light in the light exposure process.

In some embodiments, the second photoresist layer PR2 may include a (2-1)th photoresist layer PR2-1 and a (2-2)th photoresist layer PR2-2, which have different heights. The (2-2)th photoresist layer PR2-2 may have a height greater than a height of the (2-1)th photoresist layer PR2-1. The (2-2)th photoresist layer PR2-2 and the (2-1)th photoresist layer PR2-1 may have a step difference from each other.

In this phase, the (2-1)th photoresist layer PR2-1 may be patterned at a position corresponding to the half-tone portion of the photomask. The (2-2)th photoresist layer PR2-2 may be patterned at a position corresponding to the full-tone portion of the photomask.

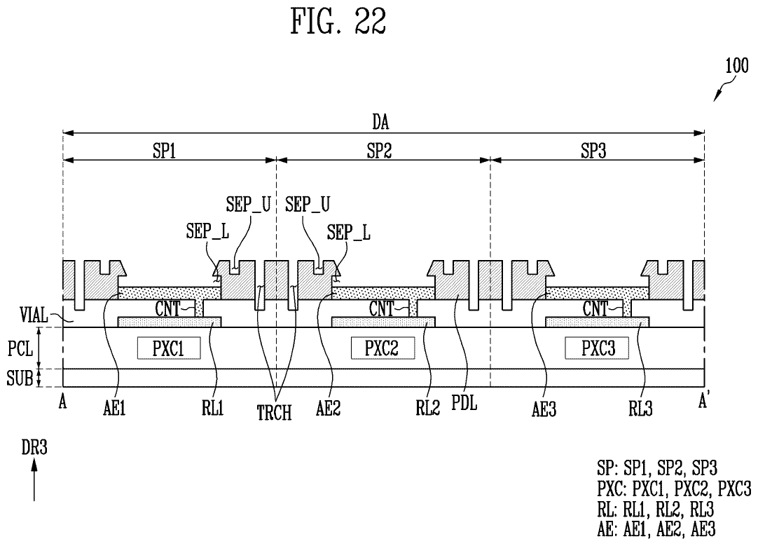

Referring to FIG. 22, at least a portion of the base pixel defining layer PDL_B may be removed, and an upper separator SEP_U and a trench TRCH may be defined.

In this phase, at least a portion of the base pixel defining layer PDL_B may be etched using an etch mask based on the (2-1)th photoresist layer PR2-1 and the (2-2)th photoresist layer PR2-2. Accordingly, the upper separator SEP_U and the trench TRCH, which have different depths, may be defined. That is, the upper separator SEP_U and the trench TRCH may be defined through the same process.

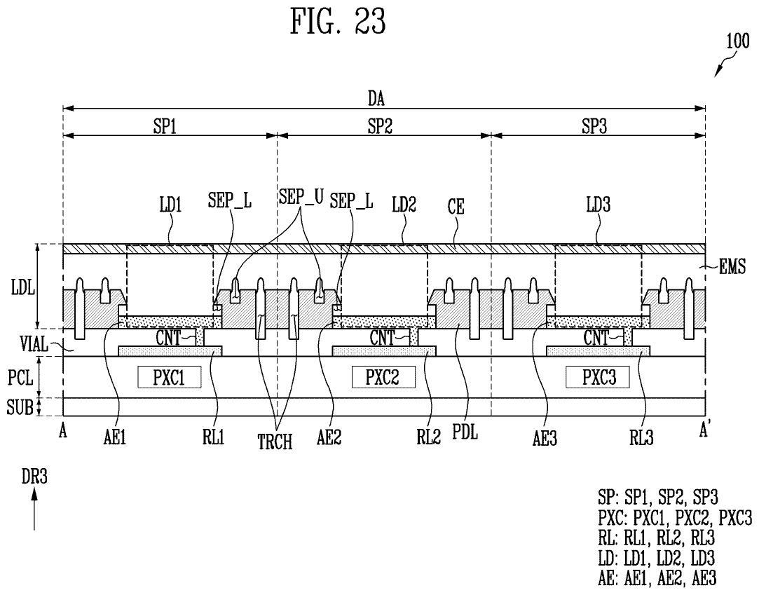

Referring to FIG. 23, an emission structure EMS may be formed throughout sub-pixels SP, and a cathode electrode CE may be formed on the emission structure EMS.

In this phase, the emission structure EMS may be formed through a process such as vacuum deposition or inkjet-printing, but the disclosure is not limited thereto.

In this phase, at least a portion of the emission structure EMS may be cut by the trench TRCH, the lower separator SEP_L, and the upper separator SEP_U.

In this phase, as the cathode electrode CE is formed throughout the sub-pixels SP, a common electrode of first to third sub-pixels SP1 to SP3 may be formed.

After that, in some embodiments, other layers such as an encapsulation layer TFE may be further disposed on the cathode electrode CE, and the display device 100 in the embodiment of the disclosure may be proved.

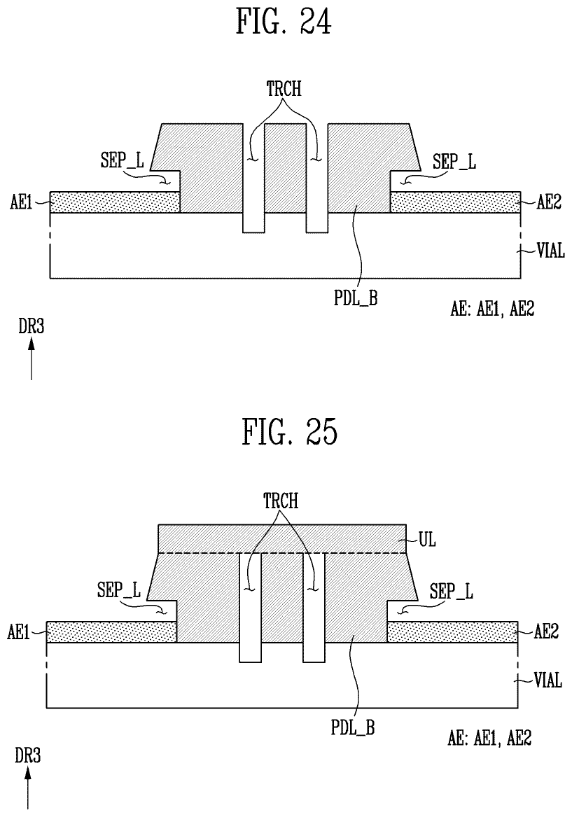

Next, a method of manufacturing a display device 100 in which a lower separator SEP_L and an upper separator SEP_U, which has a protruding structure, are defined will be described with reference to FIGS. 24 to 28.

FIGS. 24 to 28 are schematic cross-sectional views illustrating an embodiment of process steps of a method of manufacturing a display device in accordance with the disclosure. For convenience of description, FIGS. 24 to 28 are illustrated based on the cross-sectional structure described on with reference to FIGS. 12 and 13, a method of manufacturing other layers except a pixel defining layer PDL may be applied similarly to the method of manufacturing the display device 100, which is described above.

Referring to FIG. 24, in the method of manufacturing the display device 100 in the embodiment of the present, the process steps described on with reference to FIGS. 18 to 20 may be similarly performed, and an upper separator SEP_U may not be defined when a trench TRCH is defined.

In this phase, after a lower separator SEP_L is defined, a trench TRCH may be defined by performing an etching process on an upper surface of a pixel defining layer PDL. In this embodiment, since the trench TRCH is defined, and an upper separator SEP_U having a trench-type structure is not defined, an etching process may be performed using a photomask including no half-tone portion.

Referring to FIG. 25, an upper layer UL covering an upper surface of a base pixel defining layer PDL_B may be patterned on the base pixel defining layer PDL_B.

In some embodiments, the upper layer UL may include the same material as that of the base pixel defining layer PDL_B. However, the disclosure is not limited thereto. The upper layer UL may include a material different from a material of the base pixel defining layer PDL_B.

In this phase, the upper layer UL may cover an entirety of the upper surface of the base pixel defining layer PDL_B in a plan view, and cover an entirety of the trench TRCH.

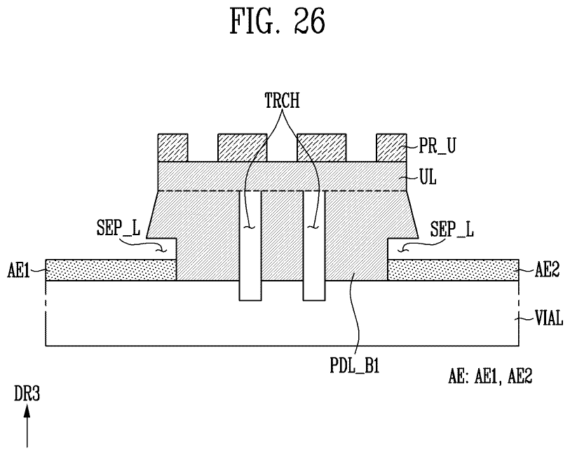

Referring to FIG. 26, an upper photoresist layer PR_U may be patterned on the upper layer UL.

In this phase, the upper photoresist layer PR_U may be patterned to have a roughly uniform thickness. The upper photoresist layer PR_U may be a layer for defining an upper separator SEP_U having a protruding structure in a subsequent process.

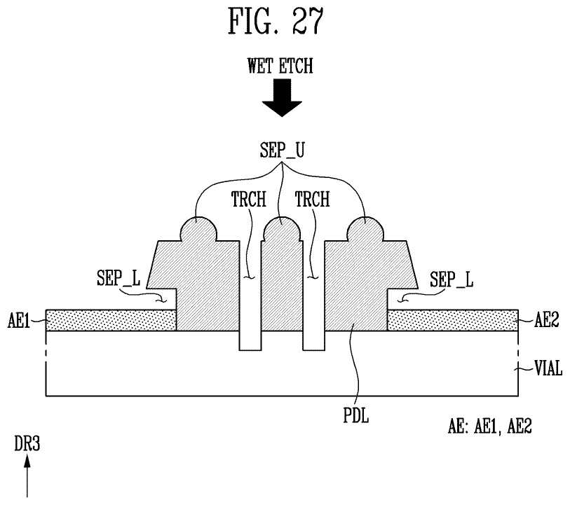

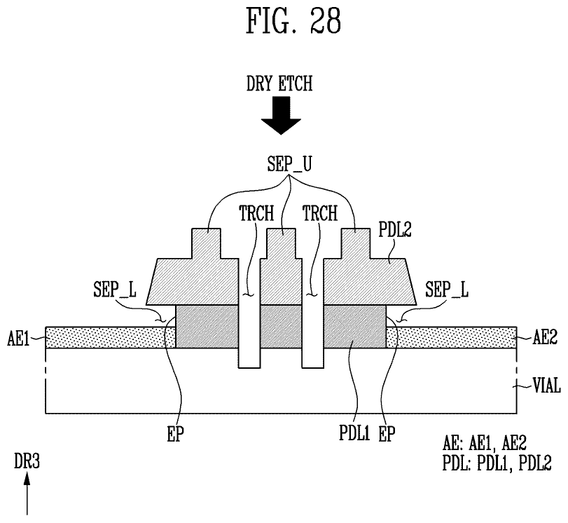

Referring to FIGS. 27 and 28, an etching process on the upper layer UL may be performed based on the upper photoresist layer PR_U, and the upper separator SEP_U having the protruding structure may be defined.

In some embodiments (refer to FIG. 27), a wet etching (WET ETCH) process on the upper layer UL may be performed, and the upper separator SEP_U may be patterned to have a relatively protruding structure having a relatively round outer surface at the upper surface of the pixel defining layer PDL.

In some embodiments (refer to FIG. 28), a dry etching (DRY ETCH) process on the upper layer UL may be performed, and the upper separator SEP_U may be patterned to have a relatively protruding structure having a polygonal section at the upper surface of the pixel defining layer PDL.

After that, in some embodiments, an emission structure EMS, a cathode electrode CE, an encapsulation layer TFE, and additional layers may be disposed, and the display device 100 in the embodiment of the disclosure may be provided.

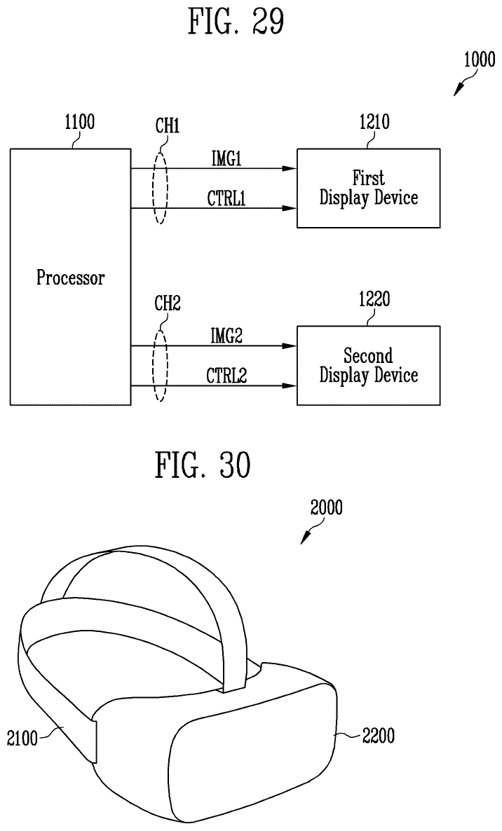

FIG. 29 is a block diagram illustrating an embodiment of the electronic device.

Referring to FIG. 29, an electronic device 1000 may include a processor 1100 and one or more display devices 1210 and 1220. The electronic device 1000 may implement a display system.

The processor 1100 may perform various tasks and various calculations. In an embodiment, the processor 1100 may include an application processor (“AP”), a graphics processing unit (“GPU”), a microprocessor, a central processing unit (“CPU”), or the like. The processor 1100 may be connected to other components of the electronic device 1000 through a bus system to control the components of the electronic device 1000.

In an embodiment, the processor 1100 may provide input image data to the display device 1210 and 1220, and the display device 1210 and 1220 may display images based on the input image data provided by the processor 1100.

In FIG. 29, it is illustrated that the electronic device 1000 includes first and second display devices 1210 and 1220. The processor 1100 may be connected to the first display device 1210 through a first channel CH1, and be connected to the second display device 1220 through a second channel CH2.

Through the first channel CH1, the processor 1100 may transmit first image data IMG1 and a first control signal CTRL1 to the first display device 1210. The first display device 1210 may display an image, based on the first image data IMG1 and the first control signal CTRL1. The first display device 1210 may be configured identically to the display device 100 described with reference to FIG. 1.

Through the second channel CH2, the processor 1100 may transmit second image data IMG2 and a second control signal CTRL2 to the second display device 1220. The second display device 1220 may display an image, based on the second image data IMG2 and the second control signal CTRL2. The second display device 1220 may be configured identically to the display device 100 described with reference to FIG. 1.

The electronic device 1000 may include a computing system for providing an image display function, such as a portable computer, a mobile phone, a smartphone, a tablet personal computer (“PC”), a smart watch, a watch phone, a portable multimedia player (“PMP”), a navigation system, or an ultra mobile computer (“UMPC”). The electronic device 1000 may include at least one of an HMD device, a VR device, an MR device, and an AR device.

In an embodiment, the electronic device 1000 may further include a memory device, a storage device, an input/output (“I/O”) device, a power supply.

The memory device may store data desired to perform the operation of the electronic device. In an embodiment, the memory device may include non-volatile memory devices such as an erasable programmable read-only memory (“EPROM”) device, an electrically erasable programmable read-only memory (“EEPROM”) device, a flash memory device, a phase change random access memory (“PRAM”) device, a resistance random access memory (“RRAM”) device, a nano floating gate memory (“NFGM”) device, a polymer random access memory (“PoRAM”) device, a magnetic random access memory (“MRAM”) device, and a ferroelectric random access memory (“FRAM”) device, and/or volatile memory devices such as a dynamic random access memory (“DRAM”) device, a static random access memory (“SRAM”) device, a mobile DRAM device, and so on, for example.

The storage device may include a solid state drive (“SSD”), a hard disk drive (“HDD”), a compact disc read-only memory (“CD-ROM”), or the like.

The I/O device may include input devices such as a keyboard, a keypad, a touchpad, a touch screen, and a mouse, and output devices such as a speaker and a printer. In an embodiment, the display device 1210, 1220 may be included in the I/O device.

The power supply may supply power desired to perform the operation of the electronic device 1000. In an embodiment, the power supply may be a power management integrated circuit (“PMIC”), for example. In an embodiment, the power supply may supply power to the display device 1210, 1220.

FIG. 30 is a perspective view illustrating an application embodiment of the electronic device shown in FIG. 29.

Referring to FIG. 30, the electronic device 1000 shown in FIG. 29 may be applied to an HMD device 2000. The HMD device 2000 may be a wearable electronic device which may be worn on a head of a user.

The HMD device 2000 may include a head mounting band 2100 and a display device accommodating case 2200. The head mounting band 2100 may be connected to the display device accommodating case 2200. The head mounting band 2100 may include a horizontal band and/or a vertical band, used to fix the HMD device 2000 to the head of the user. The horizontal band may surround a side portion of the head of the user, and the vertical band may surround an upper portion of the head of the user. However, the disclosure is not limited thereto. In an embodiment, the head mounting band 2100 may be implemented in the form of a glasses frame, a helmet or the like, for example.

The display device accommodating case 2200 may accommodate the first and second display devices 1210 and 1220 shown in FIG. 29. The display device accommodating case 2200 may further accommodate the processor 1100 shown in FIG. 29.

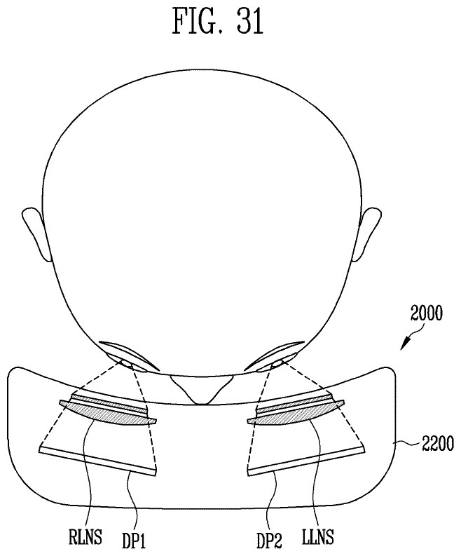

FIG. 31 is a view illustrating an HMD device shown in FIG. 30, which is worn by a user.

Referring to FIG. 31, a first display panel DP1 of the first display device 1210 and a second display panel DP2 of the second display device 1220 may be disposed in the HMD device 2000. The HMD device 2000 may further include one or more lenses LLNS and RLNS.

In the display device accommodating case 2200, a right-eye lens RLNS may be disposed between the first display panel DP1 and a right eye of the user. In the display device accommodating case 2200, a left-eye lens LLNS may be disposed between the second display panel DP2 and a left eye of the user.

An image output from the first display panel DP1 may be viewed by the right eye of the user through the right-eye lens RLNS. The right-eye lens RLNS may refract light emitted from the first display panel DP1 to face the right eye of the user. The right-eye lens RLNS may perform an optical function for adjusting a viewing distance between the first display panel DP1 and the right eye of the user.

An image output from the second display panel DP2 may be viewed by the left eye of the user through the left-eye lens LLNS. The left-eye lens LLNS may refract light emitted from the second display panel DP2 to face the left eye of the user. The left-eye lens LLNS may perform an optical function for adjusting a viewing distance between the second display panel DP2 and the left eye of the user.

In an embodiment, each of the right-eye lens RLNS and the left-eye lens LLNS may include an optical lens having a pancake-shaped section. In an embodiment, each of the right-eye lens RLNS and the left-eye lens LLNS may include a multi-channel lens including sub-areas having different optical characteristics. Each display panel may output images respectively corresponding to the sub-areas of the multi-channel lens, and the output images may be viewed by the user while respectively passing through corresponding sub-areas.

In accordance with the disclosure, there may be provided a display device, a method of manufacturing a display device, an electronic device including a display device, in which a risk such as lateral leakage may be reduced, and accordingly, display quality may be improved.

Embodiments have been disclosed herein, and although predetermined terms are employed, they are used and are to be interpreted in a generic and descriptive sense only and not for purpose of limitation. In some instances, as would be apparent to one of ordinary skill in the art as of the filing of the application, features, characteristics, and/or elements described in connection with a particular embodiment may be used singly or in any combinations with features, characteristics, and/or elements described in connection with other embodiments unless otherwise specifically indicated. Accordingly, it will be understood by those of skill in the art that various changes in form and details may be made without departing from the spirit and scope of the disclosure as set forth in the following claims.

What is claimed is:

1. A display device comprising:
a light-emitting element disposed on a substrate, the light-emitting element including:
an anode electrode, an emission structure, and a cathode electrode, which are electrically connected to each other; and
a pixel defining layer next to the anode electrode,
wherein a trench is defined in the pixel defining layer and penetrates at least a portion of the pixel defining layer, and
an upper separator is defined in an upper surface of the pixel defining layer and has a structure different from a structure of the trench.

2. The display device of claim 1, wherein the pixel defining layer defines a lower separator in an edge of an upper surface of the anode electrode and has an undercut structure.

3. The display device of claim 2, wherein the upper surface of the anode electrode is not in contact with the pixel defining layer, and
a side surface of the anode electrode is directly next to the pixel defining layer.

4. The display device of claim 1, wherein the trench entirely penetrates the pixel defining layer, and
wherein the upper separator partially penetrates the pixel defining layer.

5. The display device of claim 4, wherein the upper separator has a trench structure, and has a depth lower than a depth of the trench.

6. The display device of claim 4, wherein the upper separator has a polygonal or curved cross-sectional profile.

7. The display device of claim 4, wherein the upper separator includes a first upper separator disposed at a side of the trench and a second upper separator disposed at an opposite side of the trench opposite to the side of the trench.

8. The display device of claim 1, wherein the upper separator has a protruding structure at the upper surface of the pixel defining layer.

9. The display device of claim 8, wherein the upper separator has a polygonal or curved cross-sectional profile.

10. The display device of claim 8, wherein the trench includes a first trench and a second trench, which are spaced apart from each other, and
wherein the upper separator includes a first upper separator disposed at a side of the first trench, a second upper separator disposed between an opposite side of the first trench opposite to the side of the first trench and a side of the second trench, and a third upper separator disposed at an opposite side of the second trench opposite to the side of the second trench.

11. The display device of claim 1, wherein the pixel defining layer defines a lower separator in an edge of an upper surface of the anode electrode and has an undercut structure, and
wherein the upper separator is defined between the lower separator and the trench.

12. The display device of claim 1, wherein the pixel defining layer further defines:
a lower separator which is defined in an edge of an upper surface of the anode electrode and has an undercut structure; and
an intermediate separator defined on the lower separator, and
wherein the intermediate separator is a cavity in which a portion of a side surface of the pixel defining layer is recessed.

13. The display device of claim 1, wherein the pixel defining layer further defines a lower separator in an edge of an upper surface of the anode electrode and has an undercut structure,
wherein the pixel defining layer includes a first pixel defining layer and a second pixel defining layer on the first pixel defining layer, which include different materials from each other,
wherein the first pixel defining layer has a width narrower than a width of the second pixel defining layer, and
wherein the first pixel defining layer does not cover the upper surface of the anode electrode, is directly next to a side surface of the anode electrode, and is directly next to the lower separator.

14. The display device of claim 13, wherein the second pixel defining layer includes a (2-1)th pixel defining layer and a (2-2)th pixel defining layer, which are spaced apart from each other, and
wherein the pixel defining layer includes an intermediate pixel defining layer which has a width wider than a width of the second pixel defining layer and is disposed between the (2-1)th pixel defining layer and the (2-2)th pixel defining layer.

15. The display device of claim 1, wherein the display device is an organic light-emitting diode-on-Silicon display device.

16. A method of manufacturing a display device, the method comprising:
patterning an anode electrode on a substrate;
patterning a base pixel defining layer having an undercut structure on the anode electrode;
forming a pixel defining layer in which a trench is defined by removing at least a portion of the base pixel defining layer;
forming an emission which covers the anode electrode and the pixel defining layer; and
forming a cathode electrode on the emission structure.

17. The method of claim 16, wherein the forming the pixel defining layer includes defining an upper separator having a trench structure by removing at least a portion of the base pixel defining layer,
wherein the upper separator and the trench are defined in a same process, and
wherein the patterning the base pixel defining layer includes:
patterning a first photoresist layer on the anode electrode;
forming the base pixel defining layer covering an upper surface of the first photoresist layer and a side surface of the anode electrode; and
removing the first photoresist layer.

18. The method of claim 17, wherein the forming the pixel defining layer includes:
patterning, on the base pixel defining layer, a second photoresist layer including a (2-1)th photoresist layer and a (2-2)th photoresist layer, which have different heights, using a photomask including a half-tone portion; and
defining the trench and the upper separator by performing an etching process on the base pixel defining layer, based on the second photoresist layer.

19. The method of claim 16, wherein the forming the pixel defining layer includes:
patterning an upper layer on the base pixel defining layer; and
defining an upper separator having a protruding structure by etching the upper layer.

20. An electronic device comprising:
a processor configured to provide input image data;
a display device configured to display an image based on the input image data, the display device including:
sub-pixel areas;
a light-emitting element disposed on a substrate, the light-emitting element including:
an anode electrode, an emission structure, and a cathode electrode, which are electrically connected to each other; and
a pixel defining layer next to the anode electrode; and
a power supply configured to supply power to the display device,
wherein a trench is defined in the pixel defining layer and penetrates at least a portion of the pixel defining layer, and
an upper separator is defined in an upper surface of the pixel defining layer and has a structure different from a structure of the trench.
